(19) United States
(12) Patent Application Publication
(10) Pub. No.: US 2024/0027190 A1
(43) Pub. Date: Jan. 25, 2024

(54) SURFACE PROPERTY JUDGING METHOD AND SURFACE PROPERTY JUDGING SYSTEM

(71) Applicant: EBARA CORPORATION, Tokyo (JP)

(72) Inventors: Toshifumi KIMBA, Tokyo (JP); Kohei OHSHIMA, Tokyo (JP)

(21) Appl. No.: 18/223,360

(22) Filed: Jul. 18, 2023

(30) Foreign Application Priority Data
Jul. 22, 2022 (JP) 2022-117344

(51) Int. Cl. G01B 21/30

(52) U.S. Cl. CPC G01B 21/30; H01L 22/12

(57) ABSTRACT

A surface property judging method and a surface property judging system for a polishing pad capable of appropriately judging a surface property of the polishing pad are disclosed. The surface property judging method includes: rotating a polishing table together with a polishing pad which is supported by the polishing table; generating surface data by a surface data generator, the surface data containing a plurality of shape index values representing a surface property of the polishing pad; producing a histogram indicating a distribution of the plurality of shape index values based on the surface data; and judging the surface property of the polishing pad based on the histogram.

### CROSS REFERENCE TO RELATED APPLICATION

This document claims priority to Japanese Patent Application No. 2022-117344 filed Jul. 22, 2022, the entire contents of which are hereby incorporated by reference.

### BACKGROUND

A planarization technique for a surface of a semiconductor device has been increasingly important in a manufacturing process of semiconductor devices. The most important technique in this surface planarization is chemical mechanical polishing (CMP). The chemical mechanical polishing (hereafter referred to as CMP) is a process of polishing a substrate, such as a wafer, by placing the substrate in sliding contact with a polishing surface of a polishing pad while supplying a polishing liquid containing abrasive grains, such as silica (SiO₂), onto the polishing surface.

A polishing apparatus for performing CMP includes a polishing table that supports a polishing pad having a polishing surface, and a polishing head configured to hold a substrate and press the substrate against the polishing pad. The polishing apparatus polishes the substrate as follows. While the polishing table and the polishing pad are rotated together, a polishing liquid (typically slurry) is supplied onto the polishing surface of the polishing pad. The polishing head presses a surface of the substrate against the polishing surface of the polishing pad while rotating the substrate. The substrate is brought into sliding contact with the polishing pad in the presence of the polishing liquid. The surface of the substrate is polished by a chemical action of the polishing liquid and mechanical action(s) of the polishing pad and/or the abrasive grains contained in the polishing liquid.

After polishing of the substrate, abrasive grains and polishing debris are attached to the polishing surface of the polishing pad, and polishing performance deteriorates. Thus, dressing (conditioning) of the polishing pad by a dresser is performed to regenerate the polishing surface of the polishing pad. The dresser has hard abrasive grains, such as diamond particles fixed to a lower surface of the dresser, and the dresser regenerates the polishing surface of the polishing pad by scraping away the polishing surface of the polishing pad.

The polishing pad gradually wear as the substrate is repeatedly polished and the dressing of the polishing pad is repeatedly performed. As the polishing pad wears, an intended polishing performance may not be obtained. Therefore, it is necessary to periodically replace the polishing pad with a new one. Thus, when a use time of the polishing pad has exceeded a predetermined time, or when the number of substrates polished has exceeded a predetermined number, the polishing pad is replaced with a new one.

However, the use time of the polishing pad and the number of substrates polished indirectly indicate the wear of the polishing pad and may not appropriately reflect the wear of the polishing pad. As a result, a polishing pad that has not yet reached a service life may be replaced, or a polishing pad that has been worn beyond a service limit may continue to be used. In particular, if a polishing pad that has been excessively worn is used, a target film-thickness profile of a substrate may not be achieved. In addition, an appropriate replacement time may vary depending on individual differences in polishing pads.

### SUMMARY

Thus, there are provided a surface property judging method and a surface property judging system for a polishing pad capable of appropriately judging a surface property of the polishing pad.

Embodiments, which will be described below, relate to a surface property judging method and a surface property judging system for a polishing pad for judging a surface property of the polishing pad for polishing a substrate, such as a wafer.

In an embodiment, there is provided a surface property judging method comprising: rotating a polishing table together with a polishing pad which is supported by the polishing table; generating surface data by a surface data generator, the surface data containing a plurality of shape index values representing a surface property of the polishing pad; producing a histogram indicating a distribution of the plurality of shape index values based on the surface data; and judging the surface property of the polishing pad based on the histogram.

In an embodiment, judging the surface property of the polishing pad is performed based on a position of a peak appearing in the histogram.

In an embodiment, judging the surface property of the polishing pad is performed based on a height of a peak appearing in the histogram.

In an embodiment, the surface property judging method further comprises: generating reference surface data containing a plurality of reference shape index values representing a surface property of a past polishing pad that has reached a replacement time; and producing a reference histogram indicating a distribution of the plurality of reference shape index values based on the reference surface data, wherein judging the surface property of the polishing pad is performed based on a degree of similarity of a shape of the histogram to a shape of the reference histogram.

In an embodiment, the surface property judging method further comprises: generating reference surface data containing a plurality of reference shape index values representing a surface property of a past polishing pad that has not yet reached a replacement time; and producing a reference histogram indicating a distribution of the plurality of reference shape index values based on the reference surface data, wherein judging the surface property of the polishing pad based on the histogram comprises calculating a degree of similarity of a shape of the histogram to a shape of the reference histogram, and judging the surface property of the polishing pad based on the degree of similarity.

In an embodiment, the surface property judging method further comprises: generating a plurality of past surface data containing a plurality of past shape index values representing surface properties of a past polishing pad at a plurality of use times; producing a plurality of past histograms indicating distributions of the plurality of past shape index values based on the plurality of past surface data; and producing a predictive histogram from the plurality of past histograms, the predictive histogram indicating that the past polishing pad has reached a replacement time, wherein judging the surface property of the polishing pad based on the histogram comprises calculating a degree of similarity of a shape of the histogram to a shape of the predictive histogram, and judging the surface property of the polishing pad based on the degree of similarity.

In an embodiment, judging the surface property of the polishing pad includes judging whether the polishing pad has reached a replacement time.

In an embodiment, the surface property judging method further comprises generating an alarm when the polishing pad has reached the replacement time.

In an embodiment, judging the surface property of the polishing pad is performed by inputting a shape of the histogram into a trained model constructed by machine learning, and outputting a degree of deterioration from the trained model.

In an embodiment, producing the surface data comprises generating a plurality of region surface data by the surface data generator, the plurality of region surface data containing a plurality of shape index values representing surface properties of a plurality of measurement regions of the polishing pad, the plurality of measurement regions being arranged along a radial direction of the polishing pad, producing the histogram comprises producing a plurality of histograms corresponding to the plurality of measurement regions based on the plurality of region surface data, and judging the surface property of the polishing pad comprises judging the surface properties of the plurality of measurement regions based on the plurality of histograms.

In an embodiment, the surface data generator includes a distance sensor or a shape measuring sensor.

In an embodiment, there is provided a surface property judging system comprising: a surface data generator configured to generate surface data containing a plurality of shape index values representing a surface property of a rotating polishing pad; and an arithmetic system configured to produce a histogram indicating a distribution of the plurality of shape index values based on the surface data, and judge the surface property of the polishing pad based on the histogram.

In an embodiment, the arithmetic system is configured to judge the surface property of the polishing pad based on a position of a peak appearing in the histogram.

In an embodiment, the arithmetic system is configured to judge the surface property of the polishing pad based on a height of a peak appearing in the histogram.

In an embodiment, the arithmetic system is configured to generate reference surface data containing a plurality of reference shape index values representing a surface property of a past polishing pad that has reached a replacement time, produce a reference histogram indicating a distribution of the plurality of reference shape index values based on the reference surface data, and judge the surface property of the polishing pad based on a degree of similarity of a shape of the histogram to a shape of the reference histogram.

In an embodiment, the arithmetic system is configured to generate reference surface data containing a plurality of reference shape index values representing a surface property of a past polishing pad that has not yet reached a replacement time, produce a reference histogram indicating a distribution of the plurality of reference shape index values based on the reference surface data, calculate a degree of similarity of a shape of the histogram to a shape of the reference histogram, and judge the surface property of the polishing pad based on the degree of similarity.

In an embodiment, the arithmetic system is configured to generate a plurality of past surface data containing a plurality of past shape index values representing surface properties of a past polishing pad at a plurality of use times, produce a plurality of past histograms indicating distributions of the plurality of past shape index values based on the plurality of past surface data, produce a predictive histogram indicating that the past polishing pad has reached a replacement time from the plurality of past histograms, calculate a degree of similarity of a shape of the histogram to a shape of the predictive histogram, and judge the surface property of the polishing pad based on the degree of similarity.

In an embodiment, the arithmetic system is configured to judge whether the polishing pad has reached a replacement time.

In an embodiment, the arithmetic system is configured to generate an alarm when the polishing pad has reached the replacement time.

In an embodiment, the arithmetic system has a trained model constructed by machine learning, and the arithmetic system is configured to judge the surface property of the polishing pad by inputting a shape of the histogram into the trained model, and outputting a degree of deterioration from the trained model.

In an embodiment, the surface data generator is configured to generate a plurality of region surface data containing a plurality of shape index values representing surface properties of a plurality of measurement regions of the polishing pad, the plurality of measurement regions being arranged along a radial direction of the polishing pad, and the arithmetic system is configured to produce a plurality of histograms corresponding to the plurality of measurement regions based on the plurality of region surface data, and judge the surface properties of the plurality of measurement regions of the polishing pad based on the plurality of histograms.

In an embodiment, the surface data generator includes a distance sensor or a shape measuring sensor.

According to the above-described embodiments, the surface property judging method includes producing the histogram based on the surface data containing the plurality of shape index values representing the surface property of the polishing pad, so that the surface property of the polishing pad can be appropriately judged based on the produced histogram.

### BRIEF DESCRIPTION OF THE DRAWINGS

FIG. 1 is a plan view showing an embodiment of a polishing apparatus;

FIG. 2 is a side view of the polishing apparatus shown in FIG. 1;

FIGS. 3A to 3D are diagrams showing examples of patterns of pad grooves formed in a polishing surface of a polishing pad;

FIG. 4 is a diagram showing an example of perforations formed in the polishing surface of the polishing pad;

FIG. 5 is a schematic diagram showing an embodiment of a surface property judging system;

FIG. 6 is a diagram illustrating measuring a shape index value of the polishing surface of the polishing pad by a surface data generator;

FIG. 7 is a diagram showing a plurality of measurement points on the polishing surface of the polishing pad;

FIG. 8 is a graph showing a relationship between distance measured at the plurality of measurement points and measuring time;

FIG. 9A is a diagram illustrating measuring a flat portion of the polishing surface, where no recess is formed, by the surface data generator;

FIG. 9B is a diagram illustrating measuring a bottom portion of a recess, which is formed in the polishing surface, by the surface data generator;

FIG. 10A is a diagram illustrating measuring the polishing surface, which has been worn, by the surface data generator;

FIG. 10B is a diagram illustrating measuring the polishing surface, where polishing debris clogs recesses, by the surface data generator;

FIG. 11 is a graph showing a relationship between distance measured at the plurality of measurement points and use time;

FIG. 12 is a diagram showing an example of a histogram produced by an arithmetic system;

FIG. 13 is a diagram showing an example of a histogram changing with the use time of the polishing pad;

FIG. 14 is a diagram showing another example of the histogram changing with the use time of the polishing pad;

FIG. 15 is a diagram showing edges of the recesses formed in the polishing surface of the polishing pad are rounded;

FIG. 16 is a diagram showing a method of judging a surface property of the polishing pad based on the produced histogram;

FIGS. 17A and 17B are diagrams showing a method of comparing the produced histogram and a reference histogram;

FIGS. 18A and 18B are diagrams showing a method of producing a predictive histogram, which indicates that a past polishing pad has reached its replacement time, from a plurality of past histograms produced based on past surface data representing past surface properties of the past polishing pad;

FIGS. 19A and 19B are diagrams showing the method of producing the predictive histogram, which indicates that the past polishing pad has reached its replacement time, from the plurality of past histograms produced based on the past surface data representing the past surface properties of the past polishing pad;

FIG. 20 is a schematic diagram showing an example of a trained model that has been constructed with use of a deep learning method;

FIG. 21 is a diagram showing a plurality of measurement regions according to another embodiment of the surface property judging system;

FIG. 22 is a diagram showing an example of a plurality of histograms generated based on region surface data for the plurality of measurement regions;

FIG. 23 is a schematic diagram showing another embodiment of the surface data generator;

FIG. 24A is a schematic diagram illustrating the surface data generator shown in FIG. 23 when measuring a surface shape of the polishing pad;

FIG. 24B is a diagram showing a measurement result of the surface shape of the polishing pad shown in FIG. 24A;

FIG. 25 is a graph showing a relationship between area measured at a plurality of measuring lines and measuring time;

FIG. 26 is a graph showing a relationship between area measured at the plurality of measuring lines and use time; and

FIG. 27 is a diagram showing an example of a histogram changing with the use time of the polishing pad.

### DESCRIPTION OF EMBODIMENTS

Embodiments will now be described with reference to the drawings.

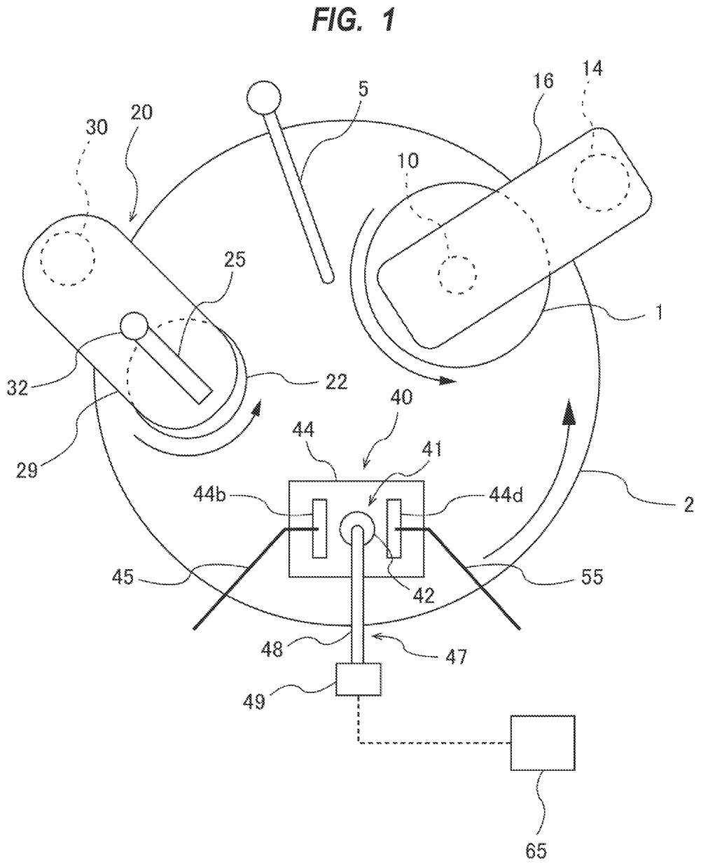

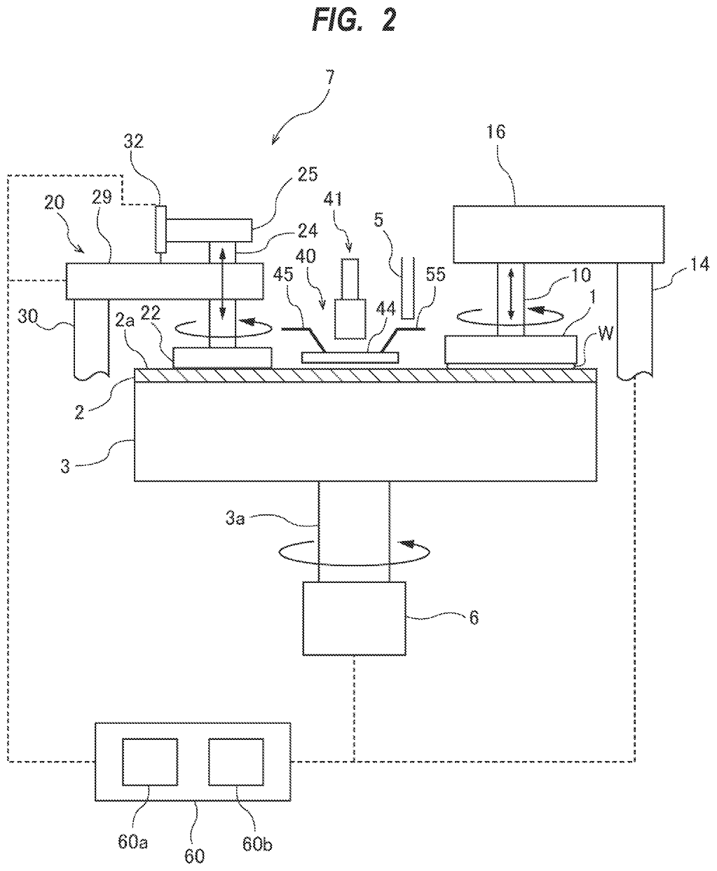

FIG. 1 is a plan view showing an embodiment of a polishing apparatus. FIG. 2 is a side view of the polishing apparatus shown in FIG. 1. The polishing apparatus is configured to chemically and mechanically polish a substrate W, such as a wafer. As shown in FIGS. 1 and 2, this polishing apparatus includes a polishing table 3 configured to support a polishing pad 2 having a polishing surface 2a, a polishing head 1 configured to press the substrate W against the polishing surface 2a, a polishing-liquid supply nozzle 5 configured to supply a polishing liquid (e.g., slurry containing abrasive grains) onto the polishing surface 2a, and a dresser 20 configured to dress (condition) the polishing surface 2a of the polishing pad 2.

The polishing apparatus further includes a polishing-head oscillating shaft 14, a polishing-head oscillating arm 16 coupled to an upper end of the polishing-head oscillating shaft 14, and a polishing-head shaft 10 rotatably supported by a free end of the polishing-head oscillating arm 16. The polishing head 1 is fixed to a lower end of the polishing-head shaft 10. The polishing head 1 is configured to be able to hold the substrate W on its lower surface. The substrate W is held such that a surface to be polished faces downward.

A polishing-head oscillating mechanism (not shown) having an electric motor or the like is disposed in the polishing-head oscillating arm 16. The polishing-head oscillating mechanism is coupled to the polishing-head oscillating shaft 14. This polishing-head oscillating mechanism is configured to oscillate the polishing head 1 and the polishing-head shaft 10 about an axis of the polishing-head oscillating shaft 14 via the polishing-head oscillating arm 16. A polishing-head rotating mechanism (not shown) having an electric motor or the like is further disposed in the polishing-head oscillating arm 16. This polishing-head rotating mechanism is coupled to the polishing-head shaft 10, and is configured to rotate the polishing-head shaft 10 and the polishing head 1 about an axis of the polishing-head shaft 10.

The polishing-head shaft 10 is coupled to a not-shown polishing-head elevating mechanism (including, e.g., a ball screw mechanism or the like). This polishing-head elevating mechanism is configured to vertically move the polishing-head shaft 10 relative to the polishing-head oscillating arm 16. This vertical movement of the polishing-head shaft 10 enables the polishing head 1 to move vertically relative to the polishing-head oscillating arm 16 and the polishing table 3.

The polishing apparatus further includes a table motor 6 configured to rotate the polishing table 3 together with the polishing pad 2. The table motor 6 is disposed below the polishing table 3, and the polishing table 3 is coupled to the table motor 6 via a table shaft 3a. The polishing table 3 and the polishing pad 2 are rotated around an axis of the table shaft 3a by the table motor 6. The polishing pad 2 is attached to an upper surface of the polishing table 3. An exposed surface of the polishing pad 2 constitutes the polishing surface 2a for polishing the substrate W, such as a wafer.

The dresser 20 includes a dressing disk 22 configured to contact the polishing surface 2a of the polishing pad 2, a dresser shaft 24 coupled to the dressing disk 22, a support block 25 configured to rotatably support an upper end of the dresser shaft 24, a dresser oscillating arm 29 configured to rotatably support the dresser shaft 24, and a dresser oscillating shaft 30 configured to support the dresser oscillating arm 29. A lower surface of the dressing disk 22 constitutes a dressing surface on which abrasive grains, such as diamond particles, are fixed.

A dresser oscillating mechanism (not shown) having an electric motor or the like is disposed in the dresser oscillating arm 29. The dresser oscillating mechanism is coupled to the dresser oscillating shaft 30. This dresser oscillating mechanism is configured to oscillate the dressing disk 22 and the dresser shaft 24 around an axis of the dresser oscillating shaft 30 via the dresser oscillating arm 29.

The dresser shaft 24 is coupled to a not-shown disk pressing mechanism (including, e.g., an air cylinder) disposed in the dresser oscillating arm 29. This disk pressing mechanism is configured to press the lower surface of the dressing disk 22, which constitutes the dressing surface, against the polishing surface 2a of the polishing pad 2 via the dresser shaft 24. The dresser shaft 24 and the dressing disk 22 can vertically move relative to the dresser oscillating arm 29. The dresser shaft 24 is coupled to a not-shown disk rotating mechanism (including, e.g., an electric motor) disposed in the dresser oscillating arm 29. This disk rotating mechanism is configured to rotate the dressing disk 22 via the dresser shaft 24 about an axis of the dresser shaft 24.

The dresser 20 includes a pad-height measuring device 32 configured to measure a height of the polishing surface 2a. The pad-height measuring device 32 employed in this embodiment is a contact displacement sensor. The pad-height measuring device 32 is fixed to the support block 25, and a contact element of the pad-height measuring device 32 is in contact with the dresser oscillating arm 29. Since the support block 25 can vertically move together with the dresser shaft 24 and the dressing disk 22, the pad-height measuring device 32 can vertically move together with the dresser shaft 24 and the dressing disk 22. On the other hand, a position in a vertical direction of the dresser oscillating arm 29 is fixed. The pad-height measuring device 32 vertically moves together with the dresser shaft 24 and the dressing disk 22 while the contact element of the pad-height measuring device 32 is in contact with the dresser oscillating arm 29. Therefore, the pad-height measuring device 32 can measure a displacement of the dressing disk 22 with respect to the dresser oscillating arm 29.

The pad-height measuring device 32 can measure the height of the polishing surface 2a via the dressing disk 22. Specifically, with the pad-height measuring device 32 being coupled to the dressing disk 22 via the dresser shaft 24, the pad-height measuring device 32 can measure the height of the polishing surface 2a during dressing of the polishing pad 2. The height of the polishing surface 2a is a distance from a preset reference plane to the lower surface of the dressing disk 22. The reference plane is an imaginary plane. For example, if the reference plane is the upper surface of the polishing table 3, the height of the polishing surface 2a corresponds to a thickness of the polishing pad 2.

In this embodiment, the pad-height measuring device 32 is a linear scale type sensor, while in one embodiment, the pad-height measuring device 32 may be a non-contact type sensor, such as a laser type sensor, an ultrasonic sensor, or an eddy current sensor. Further, in one embodiment, the pad-height measuring device 32 may be fixed to the dresser oscillating arm 29 and arranged to measure a displacement of the support block 25. In this case, the pad-height measuring device 32 can also measure the displacement of the dressing disk 22 with respect to the dresser oscillating arm 29.

In the embodiment described above, the pad-height measuring device 32 is configured to indirectly measure the height of the polishing surface 2a based on a position of the dressing disk 22 which is in contact with the polishing surface 2a, while the configuration of the pad-height measuring device 32 is not limited to this embodiment as long as the pad-height measuring device 32 can accurately measure the height of the polishing surface 2a. In one embodiment, the pad-height measuring device 32 may be a non-contact sensor, such as a laser-type sensor or an ultrasonic sensor, which is arranged above the polishing pad 2 and is configured to directly measure the height of the polishing surface 2a.

The polishing apparatus includes a polishing controller 60, and the pad-height measuring device 32 is coupled to the polishing controller 60. An output signal (i.e., a measured value of the height of the polishing surface 2a) of the pad-height measuring device 32 is transmitted to the polishing controller 60.

The polishing head 1, the polishing-liquid supply nozzle 5, the table motor 6, and the dresser 20 of the polishing apparatus are electrically connected to the polishing controller 60, and operations of the polishing head 1, the polishing-liquid supply nozzle 5, the table motor 6, and the dresser 20 are controlled by the polishing controller 60.

The polishing controller 60 is composed of at least one computer. The polishing controller 60 includes a memory 60a storing programs therein for controlling the operations of the polishing apparatus, and a processer 60b configured to perform arithmetic operations according to instructions contained in the programs. The memory 60a includes a main memory, such as a random access memory (RAM), and an auxiliary memory, such as a hard disk drive (HDD) or a solid state drive (SSD). Examples of the processer 60b include a central processing unit (CPU) and a graphics processing unit (GPU). However, the specific configuration of the polishing controller 60 is not limited to these examples.

Polishing of the substrate W is performed as follows. The polishing-liquid supply nozzle 5 supplies the polishing liquid onto the polishing surface 2a of the polishing pad 2 on the polishing table 3, while the polishing table 3 and the polishing head 1 are rotated in directions indicated by the arrows in FIGS. 1 and 2. The dressing disk 22 is arranged outside the polishing pad 2. While the substrate W is rotated by the polishing head 1, the substrate W is pressed by the polishing head 1 against the polishing surface 2a of the polishing pad 2 in the presence of the polishing liquid on the polishing pad 2. The surface of the substrate W is polished by a chemical action of the polishing liquid and mechanical actions of the abrasive grains contained in the polishing liquid and/or the polishing pad 2. Water-polishing of the substrate W may then be performed by supplying pure water onto the polishing pad 2 from a not-shown pure water nozzle.

After the polishing of the substrate W is terminated, the substrate W is moved to a position outside the polishing pad 2, and is transferred to an apparatus which performs a next process. Dressing of the polishing surface 2a of the polishing pad 2 by the dresser 20 is then performed. Specifically, pure water is supplied onto the polishing surface 2a from a not-shown pure-water nozzle, while the polishing pad 2 and polishing table 3 are rotated. The dressing disk 22 is placed on the polishing pad 2 and rubs against the polishing surface 2a of the polishing pad 2 while the dressing disk 22 is rotating. The dressing disk 22 dresses (conditions) the polishing surface 2a by slightly scraping away the polishing pad 2. The dressing of the polishing pad 2 by the dresser 20 may be performed each time one substrate W is polished, or may be performed each time a predetermined number of substrates W are polished.

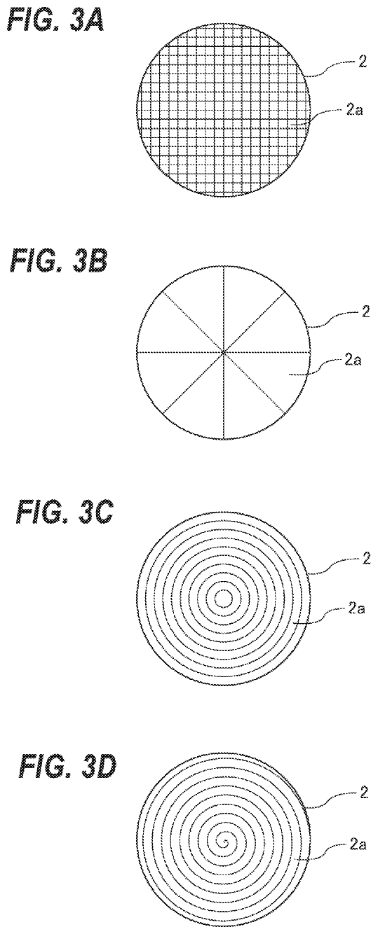

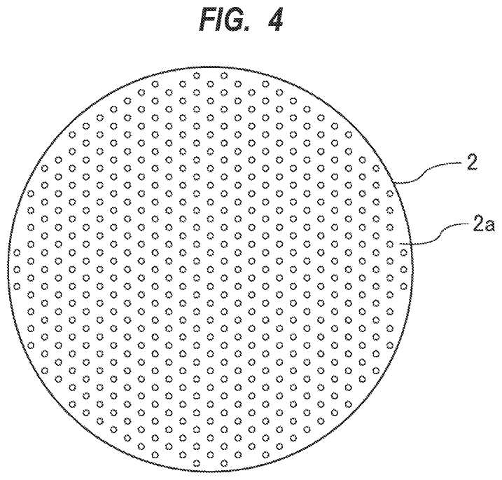

Foamed polyurethane having a large number of minute holes (pores) in the polishing surface 2a is generally used for the polishing pad 2. The polishing surface 2a of the polishing pad 2 has pad grooves with a predetermined pattern or holes called perforations. FIGS. 3A to 3D are diagrams showing examples of patterns of pad grooves formed in the polishing surface 2a of the polishing pad 2. FIG. 3A shows pad grooves having a lattice pattern, FIG. 3B shows pad grooves having a radial pattern, FIG. 3C shows pad grooves having a concentric-circle pattern, and FIG. 3D shows pad grooves having a spiral pattern. FIG. 4 is a diagram showing an example of perforations formed in the polishing surface 2a of the polishing pad 2. The perforations are formed in the entire polishing surface 2a of the polishing pad 2. Both the pad grooves and the perforations may be formed in the polishing surface 2a of the polishing pad 2. Such pad grooves and perforations are formed, for example, for spreading the polishing liquid evenly over the entire substrate W. In this specification, the pad grooves and the holes formed in the polishing pad 2 are collectively referred to as “recesses”.

As the polishing of substrate W or the dressing of the polishing pad 2 is repeated, the polishing surface 2a of the polishing pad 2 is gradually worn and polishing debris or the like clogs the holes and the pad grooves formed in the polishing surface 2a. Such a change in a surface property of the polishing pad 2 can cause deterioration of the polishing performance of the polishing pad, and as a result, a polishing rate of a substrate decreases. Therefore, it is necessary to appropriately judge the surface property of the polishing pad 2 in order to determine a replacement time of the polishing pad 2. Thus, the polishing apparatus of this embodiment further includes a surface property judging system 40 configured to judge the surface property of the polishing pad 2.

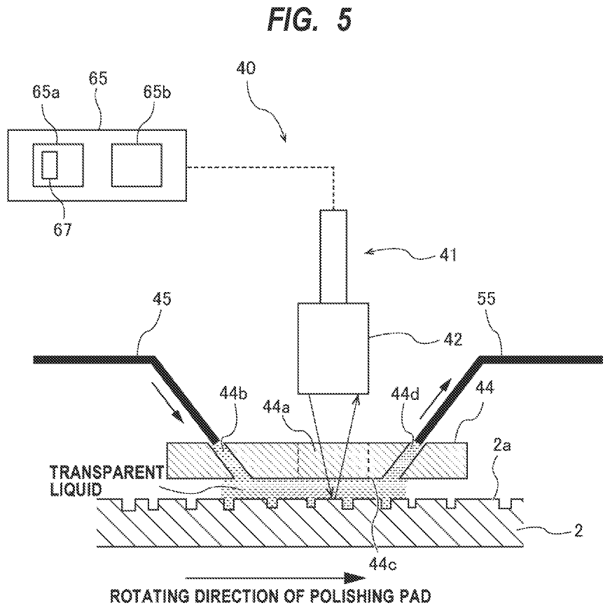

FIG. 5 is a schematic diagram showing an embodiment of a surface property judging system 40. The surface property judging system 40 includes a surface data generator 41 configured to generate surface data containing a plurality of shape index values representing the surface property of the polishing pad 2a of the polishing pad 2, a cover member 44 facing the polishing surface 2a of the polishing pad 2, a transparent-liquid supply line 45 configured to supply a transparent liquid onto the polishing pad 2, a transparent-liquid suction line 55 configured to suck the transparent liquid on the polishing pad 2, and an arithmetic system 65 configured to control the operation of the surface property judging system 40. The surface property judging system 40 is disposed so as not to be in contact with the polishing head 1 and the dresser 20 (see FIGS. 1 and 2). Therefore, the surface property judging system 40 can judge the surface property of the polishing pad 2 during polishing of the substrate W performed by the polishing head 1 or during dressing of the polishing pad 2 performed by the dresser 20.

Each component of the surface property judging system 40 is coupled to the arithmetic system 65, and operations of the surface property judging system 40 is controlled by the arithmetic system 65. The arithmetic system 65 composed of at least one computer. The arithmetic system 65 includes a memory 65a storing programs, and a processer 65b configured to perform arithmetic operations according to instructions contained in the programs. The memory includes a main memory, such as a random access memory (RAM), and an auxiliary memory, such as a hard disk drive (HDD) or a solid state drive (SSD). Examples of the processer 65b include a CPU (central processing unit) and a GPU (graphic processing unit). However, the specific configuration of the arithmetic system 65 is not limited to these examples.

In one embodiment, the arithmetic system 65 may be configured integrally with the polishing controller 60. More specifically, the arithmetic system 65 and the polishing controller may be composed of at least one computer including a memory storing programs therein and a processer configured to perform arithmetic operations according to instructions contained in the programs.

The surface data generator 41 is disposed above the polishing pad 2. The cover member 44 is disposed between the polishing pad 2 and the surface data generator 41. The surface data generator 41 is configured to measure the surface property of the polishing pad 2. The surface data generator 41 of this embodiment is configured to optically measure the surface property of the polishing pad 2. The cover member 44 has a facing surface 44c parallel to the polishing surface 2a of the polishing pad 2. The cover member 44 is located away from the polishing surface 2a of the polishing pad 2 (i.e., the cover member 44 is in non-contact with the polishing surface 2a). The cover member 44 has a light transmissive portion 44a on the optical path of the light emitted from a measuring head 42 of the surface data generator 41 which will be described later and the reflected light from the polishing surface 2a. The light transmissive portion 44a is a portion through which the light emitted from the measuring head 42 and the reflected light from the polishing surface 2a pass. The light transmissive portion 44a is depicted with dashed line shown in FIG. 5. The light transmissive portion 44a is made of a transparent material through which the light emitted from the measuring head 42 and the reflected light from the polishing surface 2a can pass. In this embodiment, the cover member 44 is a transparent plate, and the entire cover member 44 including the light transmissive portion 44a is made of a transparent material.

The cover member 44 has an inlet port 44b located upstream of the light transmissive portion 44a in a rotating direction of the polishing pad 2. In other words, the inlet port 44b is located upstream of the optical path of the light emitted from the measuring head 42 and the reflected light from the polishing surface 2a. In this embodiment, the inlet port 44b is located upstream of the measuring head 42 of the surface data generator 41.

The transparent-liquid supply line 45 is coupled to the inlet port 44b of the cover member 44, and is configured to supply a transparent liquid onto the polishing pad 2 through the inlet port 44b. As shown in FIG. 5, the entire cover member 44 is located away from the polishing surface 2a of the polishing pad 2. A gap is formed between the facing surface 44c of the cover member 44 and the polishing surface 2a of the polishing pad 2, so that the transparent liquid flows through this gap. The transparent liquid supplied from the transparent-liquid supply line 45 flows through the gap between the cover member 44 and the polishing surface 2a of the polishing pad 2 along the rotating direction of the polishing pad 2. The transparent liquid is, for example, pure water. The transparent liquid may be any transparent liquid, for example, KOH solution used for the polishing liquid.

A suction port 44d is formed in the cover member 44. The suction port 44d is located downstream of the light transmissive portion 44a in the rotation direction of the polishing pad 2. In other words, the suction port 44d is located downstream of the optical path of the light emitted from the measuring head 42 and the reflected light from the polishing surface 2a. In this embodiment, the suction port 44d is located downstream of the measuring head 42 of the surface data generator 41.

The transparent-liquid suction line 55 is configured to suck the transparent liquid flowing through the gap between the facing surface 44c of the cover member 44 and the polishing surface 2a of the polishing pad 2 through the suction port 44d. The transparent liquid supplied from the transparent-liquid supply line 45 flows through the gap between the cover member 44 and the polishing surface 2a of the polishing pad 2 along the rotating direction of the polishing pad 2, and is sucked by the transparent-liquid suction line 55. More specifically, the transparent liquid supplied from the transparent-liquid supply line 45 through the inlet port 44b flows from the inlet port 44b via the light transmissive portion 44a toward the suction port 44d, and is sucked through the suction port 44d by the transparent-liquid suction line 55. The sucked transparent liquid is discharged out of the transparent-liquid suction line 55. In one embodiment, a flow rate of the transparent liquid supplied from the transparent-liquid supply line 45 is higher than a flow rate of the transparent liquid sucked by the transparent-liquid suction line 55.

According to this embodiment, the flow of the transparent liquid from the inlet port 44b to the suction line 44d is formed in the gap between the facing surface 44c of the cover member 44 and the polishing surface 2a of the polishing pad 2, so that the optical path during the measuring of the surface property of the polishing pad 2 can be filled with the transparent liquid. Such a configuration enables stable measuring, because bubbles or gas layers (or gas-liquid interface), which may be a disturbance in optical measuring by the surface data generator 41, is not present in the measuring optical path. In addition, since the inlet port 44b is located directly above the gap between the facing surface 44c of the cover member 44 and the polishing surface 2a of the polishing pad 2, the transparent liquid can be smoothly supplied into the gap. No turbulence is generated in the flow of the transparent liquid when the transparent liquid flows into the gap, so that the generation of bubbles can be prevented.

Furthermore, a flow of the transparent liquid out of the cover member 44 can be prevented by sucking the transparent liquid on the polishing pad 2 by the transparent-liquid suction line 55. Therefore, when the surface property of the polishing pad 2 is measured during polishing of the substrate W using the polishing liquid, the polishing liquid can be prevented from being diluted by the transparent liquid. In addition, the surface property of the polishing pad 2 can be measured during polishing of the substrate W under conditions that the substrate W is actually being polished with the polishing liquid.

The configuration of the surface property judging system 40 is not limited to this embodiment. In one embodiment, the surface property judging system 40 may not include the transparent-liquid suction line 55, and the cover member 44 may not have the suction port 44d. In another embodiment, the surface property judging system 40 may not include the cover member 44, the transparent-liquid supply line 45, and the transparent-liquid suction line 55. In still another embodiment, the measuring of the shape index value of the polishing pad 2 by the surface data generator 41 may be performed during water-polishing of the substrate W while supplying pure water onto the polishing pad 2 from a not-shown pure-water nozzle. Alternatively, the measuring of the shape index value of the polishing pad 2 by the surface data generator 41 may be performed while supplying the transparent liquid from a not-shown dedicated transparent-liquid supply nozzle.

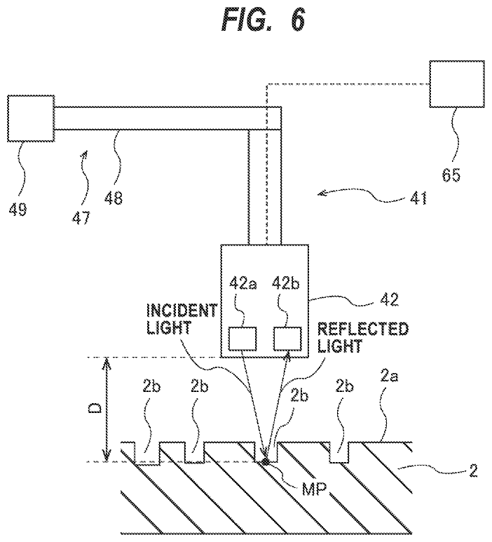

FIG. 6 is a diagram illustrating the surface data generator 41 when measuring the shape index value of the polishing surface 2a of the polishing pad 2. In FIG. 6, for the purpose of descriptions, depiction of the cover member 44 and the transparent-liquid supply line 45 is omitted. The surface data generator 41 includes a measuring head 42. The measuring head 42 of this embodiment is a distance sensor configured to measure a distance from a preset reference plane to a target object. An example of the measuring head 42 is a non-contact laser displacement sensor, which may by a commercially-available spectral interference laser displacement meter, multi-color laser displacement meter, or the like. The measuring head 42 includes a light source 42a configured to emit a laser beam, and a light receiving element 42b configured to receive reflected light from the target object. The reference plane is an imaginary plane, which may be, for example, a plane including a lower end of the measuring head 42.

The measuring head 42 is configured to measure a distance D to the polishing surface 2a of the polishing pad 2 as the shape index value representing the surface property. The measuring head 42 is disposed above the polishing surface 2a of the polishing pad 2, and the lower end of the measuring head 42 is oriented toward the polishing surface 2a of the polishing pad 2. In this embodiment, the reference plane is set to a plane including the lower end of the measuring head 42. Therefore, the distance D is a distance from the lower end of the measuring head 42 to a measurement point MP on the polishing surface 2a. The measuring head 42 directs the light (laser light) from the light source 42a to the polishing surface 2a of the polishing pad 2a, and receives the reflected light from the polishing surface 2a by the light receiving element 42b. The measuring head 42 measures the distance D to the measurement point MP on the polishing pad 2 based on the reflected light. In FIGS. 5 and 6, the optical path of the light emitted from the light source 42a is different from the optical path of the reflected light received by the light receiving element 42b, while the optical path of the light emitted from the light source 42a may be the same as the optical path of the reflected light received by the light receiving element 42b.

In one embodiment, the surface data generator 41 may be configured to measure the shape index value of the polishing pad 2 with ultrasound. An example of the measuring head 42 is an ultrasonic distance sensor. In this case, the surface property judging system 40 may not include the cover member 44, the transparent-liquid supply line 45, and the transparent-liquid suction line 55 shown in FIG. 5. Alternatively, the cover member 44 may have, instead of the light transmissive portion 44a, a not-shown through-hole through which the lower end of the measuring head 42 passes, and the facing surface 44c of the cover member 44 may be located above the lower end of the measuring head 42. When the gap between the facing surface 44c of the cover member 44 and the polishing surface 2a of the polishing pad 2 is filled with the transparent liquid, the lower end of the measuring head 42 is immersed in the transparent liquid. The ultrasonic wave emitted from the measuring head 42 propagates through the transparent liquid, and is reflected by the polishing surface 2a of the polishing pad 2.

In one embodiment, the surface property judging system 40 may include a plurality of surface data generators 41. The plurality of surface data generators 41 may have the same type of a plurality of measuring heads 42, may have a plurality of measuring heads 42 configured to measure with different measurement spot diameters, or may have different types of measuring heads 42, such as a non-contact laser displacement sensor, a ultrasonic distance sensor, and the like.

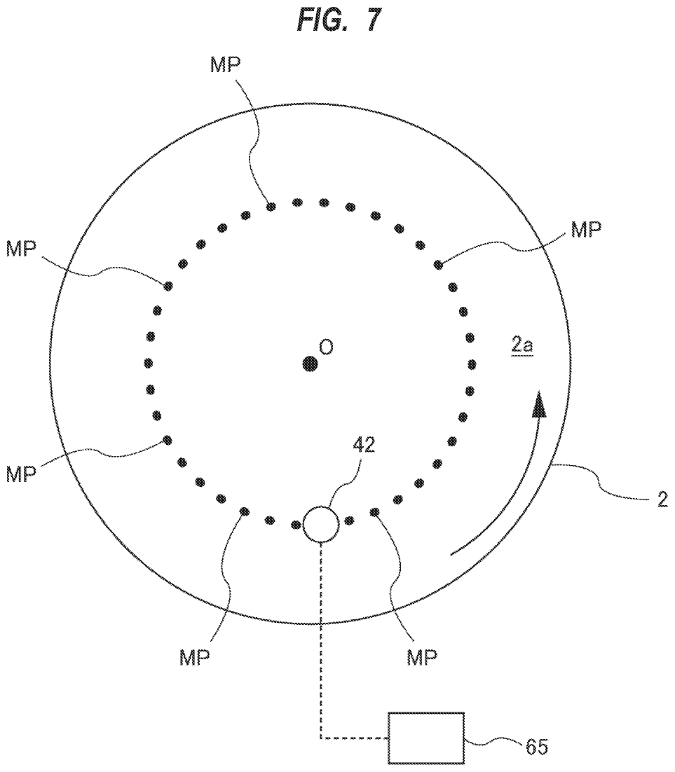

FIG. 7 is a diagram showing a plurality of measurement points MP on the polishing surface 2a of the polishing pad 2. The measuring head 42 directs the light to the polishing surface 2a of the rotating polishing pad 2 at predetermined time intervals (e.g., every 5 milliseconds), and measures the distance D to the polishing surface 2a of the polishing pad 2 based on the reflected light from the polishing surface 2a. As shown in FIG. 7, the plurality of measurement points MP are located at equal intervals on a circumference of a circle centered at a rotation center O of the polishing pad 2. The measuring head 42 continuously measures the distance D to the polishing surface 2a at the plurality of measurement points MP for a predetermined period of time. In one embodiment, a plurality of measured values of the distance D at each one of the plurality of measurement points MP may be obtained in one continuous measuring operation. One continuous measuring operation may be performed each time one substrate W is polished, or may be performed each time a predetermined number of substrates W are polished.

As shown in FIGS. 1 and 6, the surface property judging system 40 may further include a measuring-head moving mechanism 47 coupled to the measuring head 42. The measuring-head moving mechanism 47 is configured to be able to move the measuring head 42 in radial direction of the polishing table 3 and the polishing pad 2. The measuring-head moving mechanism 47 is coupled to the arithmetic system 65, and operations of the measuring-head moving mechanism 47 are controlled by the arithmetic system 65.

In one embodiment, the measuring head 42 may be moved in the radial direction of the polishing pad 2 by the measuring-head moving mechanism 47 during the measuring of the shape index value of the polishing pad 2. The measuring-head moving mechanism 47 includes a measuring-head arm 48 supporting the measuring head 42, and an actuator 49 coupled to the measuring-head arm 48. The actuator 49 is disposed outside the polishing table 3. The actuator 49 may be constituted of a combination of a motor and a torque transmission mechanism (e.g., including gears).

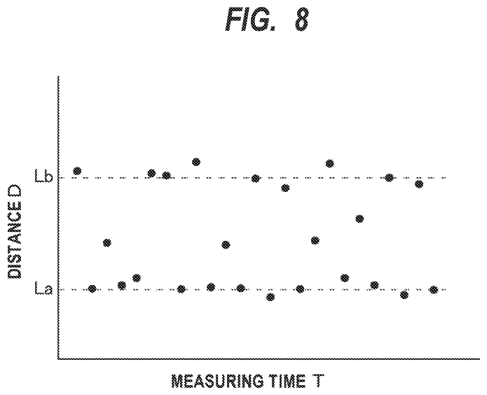

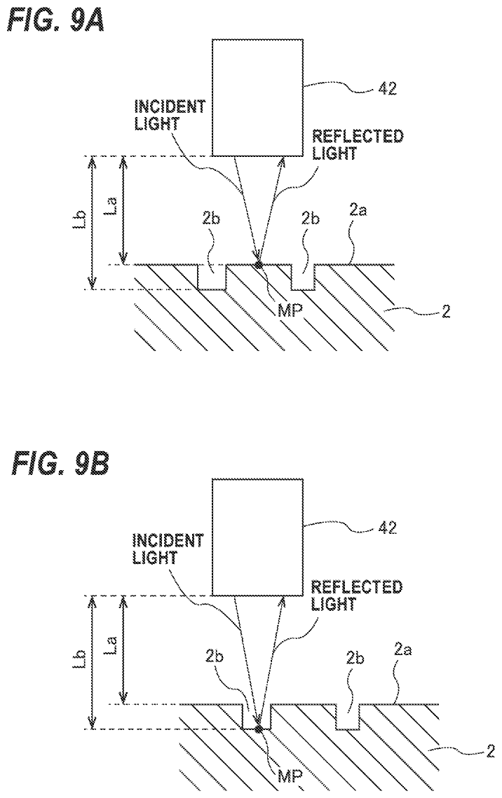

FIG. 8 is a graph showing a relationship between the distance D measured at the plurality of measurement points and measuring time T. In FIG. 8, vertical axis represents the distance D, and horizontal axis represents the measuring time T. The graph shown in FIG. 8 has been obtained by rotating the polishing pad 2 and measuring the plurality of measurement points MP on the polishing surface 2a by the measuring head 42 in one continuous measuring operation. The polishing pad 2 used in this measuring is in an initial condition of use with no wear. Measured values representing the distance D close to a value La are measured values obtained when the measuring head 42 measures the distance D to a flat portion where a recess 2b is not formed in the polishing surface 2a, as shown in FIG. 9A. Measured values representing the distance D close to a value Lb are measured values obtained when the measuring head 42 measures the distance D to a bottom of the recess 2b formed in the polishing surface 2a, as shown in FIG. 9B.

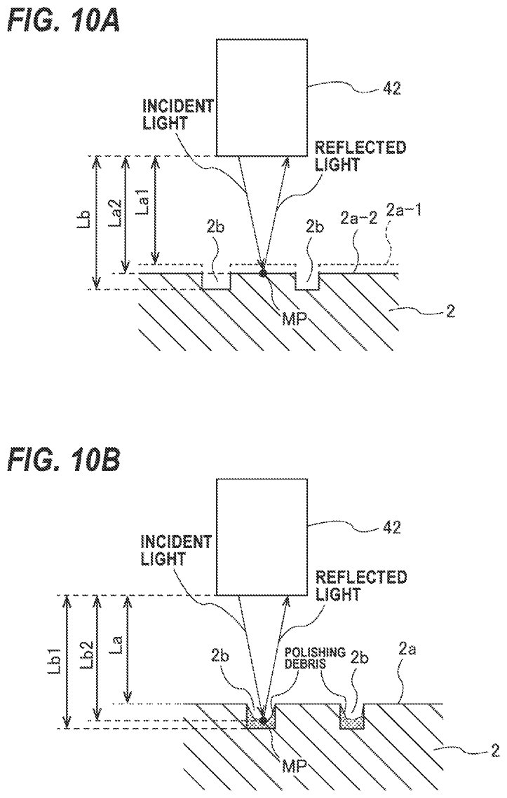

As shown in FIG. 10A, as the polishing of the substrate W or the dressing of the polishing pad 2 is repeated, the polishing pad 2 is worn from a polishing surface 2a-1 before wear to a polishing surface 2a-2. A relationship between a measured value La1 of the distance D before wear and a measured value La2 of the distance D after wear is La1<La2. In other words, the value of the distance D corresponding to the measured value La shown in FIG. 8 becomes larger as the polishing pad 2 is worn.

As shown in FIG. 10B, as the polishing of the substrate W or the dressing of the polishing pad 2 is repeated, the polishing debris or the like clogs the recess 2b formed in the polishing surface 2a of the polishing pad 2. When the measuring head 42 measures the recess 2b clogged with the polishing debris, the light from the measuring head 42 is reflected by a surface of the polishing debris in the recess 2b. A relationship between a measured value Lb1 of the distance D to the bottom of the recess 2b before clogged with the polishing debris and a measured value Lb2 of the distance D to the surface of the polishing debris clogging the recess 2b is Lb1>Lb2. In other words, as the polishing debris or the like clogs the recess 2b of the polishing pad 2, the value of the distance D corresponding to the measured value Lb shown in FIG. 8 becomes smaller.

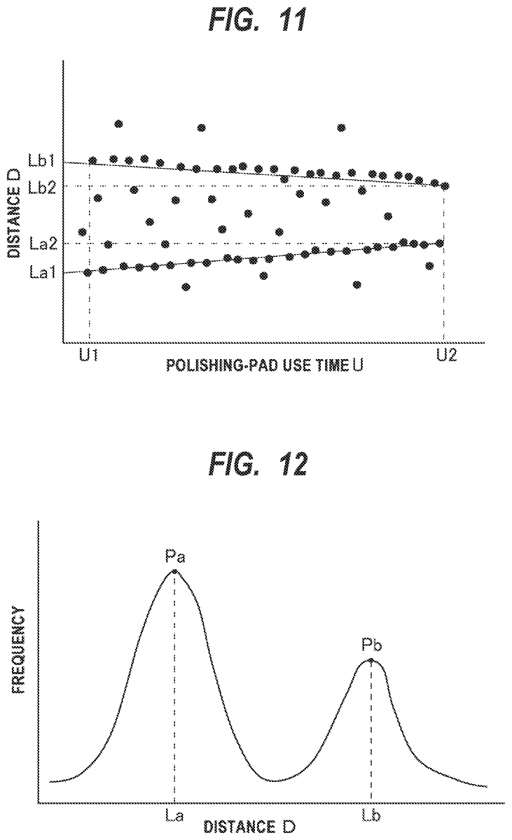

FIG. 11 is a graph showing a relationship between the distance D measured at the plurality of measurement points MP and polishing-pad use time U. FIG. 11 is a graph plotting the measured values of the distance D obtained by a plurality of continuous measuring operations that have been conducted from the beginning to the end of use of the polishing pad 2. The graph shown in FIG. 11 may be a graph plotting a relationship between averages of the measured values La and Lb obtained in each of the plurality of continuous measuring operations and the polishing-pad use time U. In FIG. 11, vertical axis represents the distance D, and horizontal axis represents the polishing-pad use time U. The measured value of the distance D changes with the polishing-pad use time U. As described with reference to FIG. 10A, the flat portion of the polishing pad 2 wears as the polishing pad 2 is used over time. As shown in FIG. 11, the measured value of the distance D becomes larger from the measured value La1 when the polishing pad 2 has not been worn (use time U1) to the measured value La2 when the polishing pad 2 has been worn (use time U2). Therefore, degree of wear of the polishing pad 2 can be estimated from the change in the measured value of the distance D.

As described with reference to FIG. 10B, the polishing debris or the like clogs the recess 2b of the polishing pad 2 as the polishing pad 2 is used over time. As shown in FIG. 11, the measured value of the distance D becomes smaller from the measured value Lb1 when the recess 2b of the polishing pad 2 is not clogged (use time U1) to the measured value Lb2 when the recess 2b of the polishing pad 2 is clogged (use time U2). Therefore, degree of clogging of the recess 2b of the polishing pad 2 can be estimated from the change in the measured value of the distance D.

The measuring of the shape index value (the distance D in this embodiment) of the polishing pad 2 is performed during the polishing of the substrate W using the polishing liquid or the pure water, during the dressing of the polishing pad 2, after dressing of the polishing pad 2 until polishing of a next substrate is started, etc.

As shown in FIG. 5, the surface data generator 41 is coupled to the arithmetic system 65. The surface data generator 41 generates surface data containing a plurality of shape index values measured by the measuring head 42. The generated surface data are transmitted to the arithmetic system 65. The arithmetic system 65 produces a histogram indicating a distribution of the plurality of shape index values based on the surface data transmitted from the surface data generator 41. In this embodiment, the arithmetic system 65 produces a histogram indicating a distribution of a plurality of measured values of the distance D. This histogram is a current histogram that reflects the surface property of the polishing pad 2.

FIG. 12 is a diagram showing an example of the histogram produced by the arithmetic system 65. In FIG. 12, vertical axis represents frequency, and horizontal axis represents the distance D. The frequency corresponds to the number of data for each measured value of the distance D. The arithmetic system 65 produces the histogram indicating the distribution of the measured values of the distance D which are the shape index values of the polishing pad 2 obtained in one continuous measuring operation. The histogram in FIG. 12 indicates the distribution of the measured values of the distance D which are the shape index values of the polishing pad 2 obtained in one continuous measuring operation, and the histogram is produced based on the measured values of the distance D which are the shape index values shown in FIG. 8.

Two peaks Pa and Pb appear in the histogram in FIG. 12. The distance D at the peak Pa corresponds to the value La shown in FIG. 8, and the distance D at the peak Pb corresponds to the value Lb shown in FIG. 8. The arithmetic system 65 judges the surface property of the polishing pad 2 based on positions and heights of the peaks Pa and Pb or a shape of the histogram. Judging of the surface property of the polishing pad 2 includes judging whether the polishing pad 2 has reached its replacement time. The two peaks Pa and Pb appear in the histogram of this embodiment, while one peak or three or more peaks may appear in another case. In either case, the surface property of the polishing pad 2 can be judged based on position(s) and height(s) of the peak(s) or a shape of the histogram, as described below.

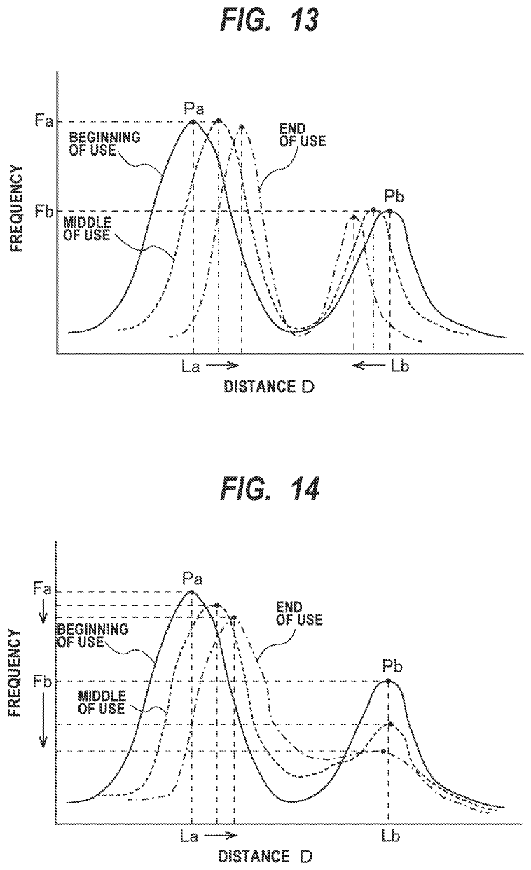

FIG. 13 is a diagram showing an example of a histogram changing with the use time of the polishing pad 2. Each of three histograms in FIG. 13 indicates a distribution of the measured values of the distance D which are the shape index values of the polishing pad 2 obtained in one continuous measuring operation. A histogram indicated by a solid line indicates a distribution of the measured values of the distance D obtained at the beginning of use of the polishing pad 2, and is the same as the histogram shown in FIG. 12. A histogram indicated by a dashed line indicates a distribution of the measured values of the distance D obtained during the middle of use of the polishing pad 2. A histogram indicated by a dashed-dotted line indicates a distribution of the measured values of the distance D obtained at the end of use of the polishing pad 2.

The beginning of use of the polishing pad 2 is a time when the polishing pad 2 has not yet been used for polishing of the substrate W, or a time when use of the polishing pad 2 has just been started. The end of use of the polishing pad 2 is a time when the polishing pad 2 has reached a service life. The middle of use of the polishing pad 2 is a time between the beginning and the end of use of the polishing pad 2, and is a time when the polishing pad 2 has reached about half of the service life.

Two peaks appear in each of the histograms of the beginning, the middle, and the end of use in FIG. 13. Positions of the two peaks Pa and Pb in each histogram move with the use time of the polishing pad 2. The position of the peak Pa, i.e., the value La of the distance D, increases with the use time of the polishing pad 2. This indicates that the polishing pad 2 has been worn with the use time of the polishing pad 2 as described with reference to FIG. 10A.

The position of the peak Pb, i.e., the value Lb of the distance D, decreases with the use time of the polishing pad 2. This indicates that an amount of the polishing debris clogging the recess 2b of the polishing surface 2a increases with the use time of the polishing pad 2 as described with reference to FIG. 10B.

A height of the peak Pa, i.e., a frequency Fa of the value La of the distance D, hardly changes with the use time of the polishing pad 2. A height of the peak Pb, i.e., a frequency Fb of the value Lb of the distance D, also hardly changes with the use time of the polishing pad 2.

FIG. 14 is a diagram showing another example of the histogram changing with the use time of the polishing pad 2. Similar to FIG. 13, each of three histograms in FIG. 14 indicates a distribution of the measured values of the distance D which are the shape index values of the polishing pad 2 obtained by one continuous measuring operation. More specifically, these three histograms indicate distributions of the measured values of the distance D obtained in the beginning, the middle, and the end of use, respectively. In the example of FIG. 14, the surface property of the polishing pad 2 changes in a manner different from that of the example of FIG. 13.

Two peaks appear in each of the histograms of the beginning, the middle, and the end of use in FIG. 14. The position of the peak Pa in each histogram, i.e., the value La of the distance D, increases with the use time of the polishing pad 2. This indicates that the polishing pad 2 has been worn with the use time of the polishing pad 2.

The position of the peak Pb, i.e., the value Lb of the distance D, hardly changes with the use time of the polishing pad 2. This indicates that the recess 2b formed in the polishing surface 2a is not clogged with the polishing debris, although the use time of the polishing pad 2 increases.

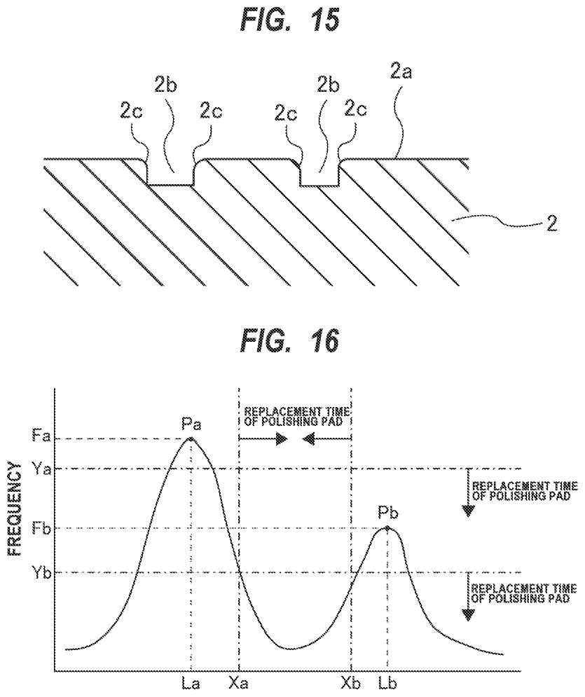

The height of the peak Pa, i.e., the frequency Fa of the value La of the distance D, decreases with the use time of the polishing pad 2. In addition, the height of the peak Pb, i.e., the frequency Fb of the value Lb of the distance D, decreases significantly with the use time of the polishing pad 2. These indicate that the distribution of the measured value of the distance D changes with the use time of the polishing pad 2, and as a result, the number of measured values of the distance D between the value La and the value Lb increases. Such a change in the distribution of the distance D indicates, for example, that the shapes of the edges 2c of the recesses 2b formed in the polishing surface 2a of the polishing pad 2 are changed and are rounded as shown in FIG. 15. When the edges 2c of the recesses 2b are rounded, the polishing performance of the polishing pad 2 changes.

An advantage of using the histogram is to graph the measured values at the plurality of measurement points instead of the measured value at one measurement point of the polishing pad 2, so that the surface property of the polishing pad 2 can be appropriately judged. By using the histogram in this way, various manners of changes in the surface property of the polishing pad 2 can be determined based on a change in the distribution of the measured value of the distance D which is the shape index value of the polishing pad 2. Therefore, the replacement time of the polishing pad 2 can be appropriately judged.

The arithmetic system 65 judges the surface property of the polishing pad 2 based on the produced histogram. In one embodiment, the arithmetic system 65 judges the surface property of the polishing pad 2 based on the position(s) of the peak(s) appearing in the histogram. FIG. 16 is a diagram showing a method of judging the surface property of the polishing pad 2 based on the produced histogram. As shown in FIG. 16, when the position of the peak Pa appearing in the histogram, i.e., the value La of the distance D, is larger than a predetermined position threshold value Xa, the arithmetic system 65 judges the surface property of the polishing pad 2 such that “the polishing pad 2 has reached a replacement time”. In other words, the arithmetic system 65 can judge the surface property of the polishing pad 2 such that “the polishing pad 2 has reached a replacement time” when the polishing pad 2 has exceeded a predetermined degree of wear.

Further, when the position of the peak Pb appearing in the histogram, i.e., the value Lb of the distance D, is smaller than a predetermined position threshold value Xb, the arithmetic system 65 judges the surface property of the polishing pad 2 such that “the polishing pad 2 has reached a replacement time”. In other words, the arithmetic system 65 can judge the surface property of the polishing pad 2 such that “the polishing pad 2 has reached a replacement time” when a thickness of the polishing debris or the like clogging the recess 2b formed in the polishing surface 2a of the polishing pad 2 has exceeded a predetermined thickness.

The arithmetic system 65 may judge the surface property of the polishing pad 2 based on either the position of the peak Pa or the position of the peak Pb appearing in the histogram. Alternatively, the arithmetic system 65 may judge the surface property of the polishing pad 2 such that “the polishing pad 2 has reached a replacement time” when the position of the peak Pa is larger than the predetermined position threshold value Xa and the position of the peak Pb is smaller than the predetermined position threshold value Xb.

In another embodiment, the arithmetic system 65 judges the surface property of the polishing pad 2 based on the height of peaks appearing in the histogram. As shown in FIG. 16, when the height of the peak Pa appearing in the histogram, i.e., the frequency Fa of the value La of the distance D, is smaller than a predetermined height threshold value Ya, the arithmetic system 65 judges the surface property of the polishing pad 2 such that “the polishing pad 2 has reached a replacement time”. Further, when the height of the peak Pb appearing in the histogram, i.e., the frequency Fb of the value Lb of the distance D, is smaller than a predetermined height threshold value Yb, the arithmetic system 65 judges the surface property of the polishing pad 2 such that “the polishing pad 2 has reached a replacement time”. Thus, as described with reference to FIG. 15, when the shape of the polishing surface 2a of the polishing pad 2 has changed beyond an allowable level, the arithmetic system 65 can judge the surface property of the polishing pad 2 such that “the polishing pad 2 has reached a replacement time”.

The arithmetic system 65 may judge the surface property of the polishing pad 2 based on either the height of the peak Pa or the height of the peak Pb appearing in the histogram. Alternatively, the arithmetic system 65 may judge the surface property of the polishing pad 2 such that “the polishing pad 2 has reached a replacement time” when the height of peak Pa is smaller than the predetermined height threshold value Ya and the height of peak Pb is smaller than the predetermined height threshold value Yb.

In still another embodiment, when a ratio of the heights of the peaks Pa and Pb, i.e., a ratio Fa/Fb between the frequency Fa of the value La of the distance D and the frequency Fb of the value Lb of the distance D, is larger than a predetermined ratio threshold value or when the ratio Fa/Fb is smaller than a predetermined ratio threshold value, the arithmetic system 65 may judge the surface property of the polishing pad 2 such that “the polishing pad 2 has reached a replacement time”. When the ratio Fb/Fa of the heights of the peaks Pa and Pb is larger than a predetermined ratio threshold value or when the ratio Fb/Fa is smaller than a predetermined ratio threshold value, the arithmetic system 65 may judge the surface property of the polishing pad 2 such that “the polishing pad 2 has reached a replacement time”.

In still another embodiment, the arithmetic system 65 may judge the surface property of the polishing pad 2 using a reference histogram produced based on reference surface data representing a surface property of a past polishing pad that have reached a replacement time. The surface data generator 41 generates the reference surface data containing a plurality of reference shape index values representing a surface property of a past polishing pad that have reached a replacement time. The arithmetic system 65 produces the reference histogram indicating a distribution of the plurality of reference shape index values based on the reference surface data.

A specific example of the reference histogram may be a plurality of reference histograms generated based on reference surface data of a plurality of past polishing pads that are judged to have reached pad replacement times due to events, such as decreasing of a polishing rate and/or increasing of defects. The plurality of reference histograms may include both a reference histogram produced based on a past polishing pad that have reached a replacement time due to wear of that polishing pad, and a reference histogram produced based on a past reference histogram that has reached a replacement time due to clogging of recesses of that polishing pad with polishing debris or the like. The arithmetic system 65 can judge the surface property of polishing pad 2 in parallel by using the plurality of reference histograms that reflect degradation of the polishing pad due to wear of the polishing pad and clogging of the recesses. In one embodiment, a single reference histogram generated by processing, such as averaging, the plurality of reference histograms may be used.

Measuring of the reference shape index value and generating of the reference surface data containing the plurality of reference shape index values are performed in the same manner as measuring of the shape index value performed by the surface data generator 41 and generating of the surface data containing the plurality of shape index values described above. The produced reference histogram is stored in the memory 65a of the arithmetic system 65. As described with reference to FIGS. 13 and 14, since the surface property of the polishing pad 2 may change in various manners, a plurality of reference histograms may be stored in the memory 65a of the arithmetic system 65.

The arithmetic system 65 compares a shape of the histogram produced based on the surface data of the polishing pad 2 with a shape of the reference histogram, and calculates a degree of similarity of the shape of the histogram to the shape of the reference histogram. Calculating of the degree of similarity may be performed using a known method, such as, for example, the least-square method, or a method using a deviation, a cosine similarity, or the Euclidean distance between the histogram produced based on the surface data of the polishing pad 2 and the reference histogram.

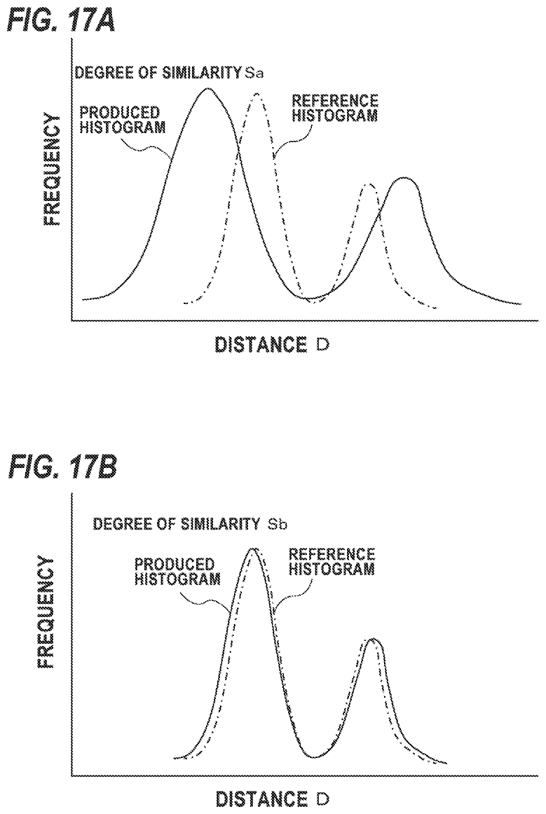

FIGS. 17A and 17B are diagrams showing a method of comparing the produced histogram with the reference histogram. The degree of similarity of the shape of the histogram to the shape of the reference histogram shown in FIG. 17A is denoted by Sa, and the degree of similarity of the shape of the histogram to the shape of the reference histogram shown in FIG. 17B is denoted by Sb. The degree of similarity is a numeric value indicating a degree of similarity of the shape of the histogram to the shape of the reference histogram, and can be expressed by a predefined manner, such as a percentage of 0% to 100%, a value of 1 to 10, or a scale of 1 to 5. For example, when the degree of similarity is expressed by a percentage of 0% to 100%, a degree of similarity of 0% indicates that the histogram is not at all similar to the reference histogram, and a degree of similarity of 100% indicates that the histogram matches the reference histogram.

The degree of similarity Sb is a numeric value indicating that the degree of similarity is higher than the degree of similarity Sa, which means that the shape of the histogram shown in FIG. 17B is more similar to the shape of the reference histogram than the shape of the histogram shown in FIG. 17A. For example, when the degree of similarity is represented by a percentage of 0% to 100%, the degree of similarity Sa is 40% and the degree of similarity Sb is 90%.

The arithmetic system 65 judges the surface property of the polishing pad 2 based on the calculated degree of similarity. In one embodiment, the arithmetic system 65 judges the surface property of the polishing pad 2 such that “the polishing pad 2 has reached a replacement time” when the calculated degree of similarity is larger than a predetermined similarity threshold value. The degree of similarity and the predetermined similarity threshold value may be expressed by a percentage of 0% to 100%. For example, the arithmetic system 65 may calculate the degree of similarity between the shape of the histogram produced based on the surface data of the polishing pad 2 and the shape of the reference histogram produced based on the reference surface data representing the surface property of the past polishing pad that has reached a replacement time, and may judge the surface property of the polishing pad 2 such that “the polishing pad 2 has reached a replacement time” when the degree of similarity is larger than the predetermined similarity threshold value of 90%.

According to this embodiment, a degree of deterioration of the polishing pad 2 can be determined from the degree of similarity of the histogram. For example, when the calculated degree of similarity is 50%, the degree of deterioration of the polishing pad 2 can be determined to be half of the degree of deterioration at the replacement time of the polishing pad 2.

The shape of the histogram to be compared may be a shape of the entire histogram or a shape of a part of the histogram. For example, the degree of similarity may be calculated by comparing a shape of a part of the histogram including a specific peak and its surroundings with a shape of a part of the reference histogram including a specific peak and its surroundings.

In still another embodiment, the arithmetic system 65 may judge the surface property of the polishing pad 2 using a reference histogram produced based on reference surface data representing a surface property of a past polishing pad that has not yet reached a replacement time. The surface data generator 41 generates the reference surface data containing a plurality of reference shape index values representing the surface property of the past polishing pad before reaching the replacement time. The arithmetic system 65 produces the reference histogram indicating a distribution of the plurality of reference shape index values based on the reference surface data. A specific example of the reference histogram produced based on the reference surface data representing the surface property of the past polishing pad that has not yet reached the replacement time may be a plurality of reference histograms produced based on reference surface data of past polishing pads that have not yet reached the replacement time due to events, such as decreasing of the polishing rate and/or increasing of defects. Alternatively, a reference histogram generated by performing processing, such as averaging, these plurality of reference histograms may be used.

Measuring of the reference shape index value and generating of the reference surface data containing the plurality of reference shape index values are performed in the same manner as measuring of the shape index value performed by the surface data generator 41 and generating of the surface data containing the plurality of shape index values described above. The produced reference histogram is stored in the memory 65a of the arithmetic system 65. As described with reference to FIGS. 13 and 14, since the surface property of the polishing pad 2 may change in various manners, a plurality of reference histograms may be stored in the memory 65a of the arithmetic system 65.

The arithmetic system 65 compares the shape of the histogram produced based on the surface data of the polishing pad 2 with the shape of the reference histogram, and calculates a degree of similarity of the shape of the histogram to the shape of the reference histogram. Comparing the shape of the produced histogram with the shape of the reference histogram is performed in the same manner as the above-described embodiment.

The arithmetic system 65 judges the surface property of the polishing pad 2 based on the calculated degree of similarity. In one embodiment, the arithmetic system 65 judges the surface property of the polishing pad 2 such that “the polishing pad 2 has reached a replacement time” when the calculated degree of similarity is smaller than a predetermined similarity threshold value. The degree of similarity and the similarity threshold value may be expressed by a percentage of 0% to 100%. For example, the arithmetic system 65 may compare the shape of the histogram produced based on the surface data of the polishing pad 2 with the shape of the reference histogram produced based on the reference surface data representing the surface property of the past polishing pad that has not yet reached a replacement time to calculate the degree of similarity, and may judge the surface property of the polishing pad 2 such that “the polishing pad 2 has reached a replacement time” when the degree of similarity is smaller than the predetermined similarity threshold value of 90%.

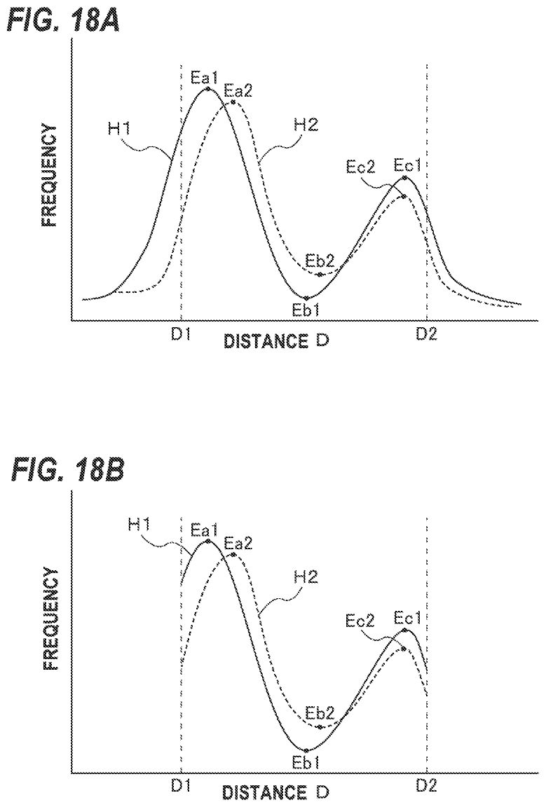

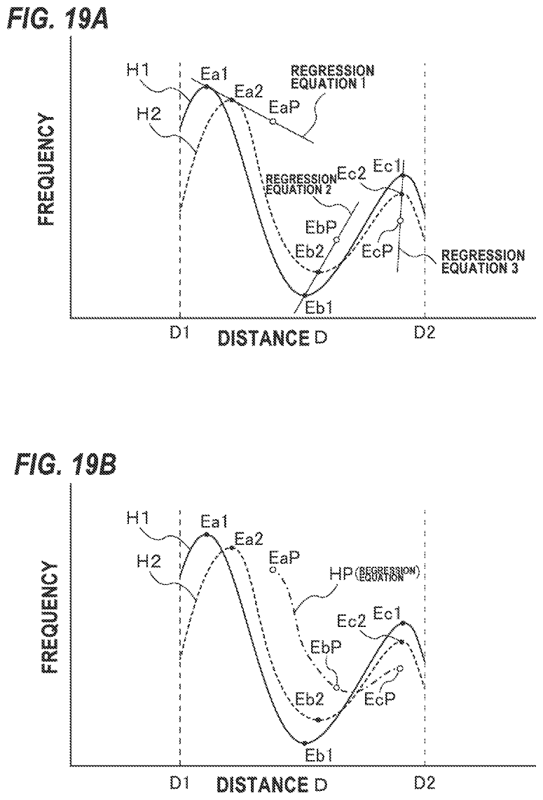

In still another embodiment, the arithmetic system 65 may produce a predictive histogram indicating that a past polishing pad has reached a replacement time from a plurality of past histograms produced based on a plurality of past surface data representing a surface property of the past polishing pad, and may judge the surface property of the polishing pad 2 using this predictive histogram. FIGS. 18A to 19B are diagrams showing a method of producing a predictive histogram from a plurality of past histograms produced based on a plurality of past surface data representing a surface property of a past polishing pad.

In FIG. 18A, a past histogram H1 expressed by a solid line is a histogram produced based on past surface data representing a surface property of the past polishing pad at a use time T1. A past histogram H2 expressed by a dashed line is a histogram produced based on past surface data representing a surface property of the past polishing pad at a use time T2. The use times T1 and T2 are both time before the past polishing pad reaches a replacement time. The use time T1 is a time before the use time T2. The past surface data (distance D in this embodiment) for producing the plurality of past histograms H1 and H2 may be surface data that has been subjected to a smoothing process to average several property index values or polynomial regression and re-plotting of the property index values as preprocessing for removing noise.

Three local extremum points Ea1, Eb1, and Ec1 appear in the past histogram H1. More specifically, two local maximum points Ea1 and Ec1 and one local minimum point Eb1 appear in the past histogram H1. Three local extremum points Ea2, Eb2, and Ec2 appear in the past histogram H2. More specifically, two local maximum points Ea2 and Ec2 and one local minimum point Eb2 appear in the past histogram H2. The number of local extremum points appearing in each of the past histograms H1 and H2 may be more than three.

As shown in FIG. 18B, the arithmetic system 65 may extract parts of the past histograms H1 and H2 within a range including these local extremum points Ea1, Eb1, Ec1, Ea2, Eb2, and Ec2. In this embodiment, the arithmetic system 65 extracts parts of the past histograms H1 and H2 within a range of distance D1 to distance D2 which includes values of distance D corresponding to the local extremum points Ea1, Eb1, Ec1, Ea2, Eb2, and Ec2.

As shown in FIG. 19A, the arithmetic system 65 determines a regression equation 1 from coordinates of the local extremum point Ea1 of the past histogram H1 and coordinates of the local extremum point Ea2 of the past histogram H2. The coordinates of the local extremum point Ea1 of the past histogram H1 are (xa1, ya1), and the coordinates of the local extremum point Ea2 of the past histogram H2 are (xa2, ya2). In this embodiment, since the number of local extremum points is two, the determined regression equation 1 is a linear expression. The arithmetic system 65 calculates from the regression equation 1 a predictive local extremum point EaP at which the past polishing pad is expected to reach the replacement time.

Specifically, a predictive use time TP is calculated in advance. This predictive use time TP is a predictive time when the past polishing pad is expected to deteriorate to such an degree that the replacement time is reached. An x-coordinate xaP of the predictive local extremum point EaP is calculated from a ratio of a difference between the use time T2 and the predictive use time TP to a difference between the use time T1 and the use time T2, and a difference between the x-coordinate xa1 of the local extremum point Ea1 and the x-coordinate xa2 of the local extremum point Ea2. Further, a y-coordinate yaP of the predicted local extremum point EaP can be determined by substituting the calculated x-coordinate xaP of the predicted local extremum point EaP into the regression equation 1.

The arithmetic system 65 determines a regression equation 2 from coordinates of the local extremum point Eb1 of the past histogram H1 and coordinates of the local extremum point Eb2 of the past histogram H2. The coordinates of the local extremum point Eb1 of the past histogram H1 are (xb1, yb1), and the coordinates of the local extremum point Eb2 of the past histogram H2 are (xb2, yb2). In this embodiment, since the number of local extremum points is two, which are the local extremum points Eb1 and Eb2, the regression equation 2 determined is a linear expression. In the same manner as determining the coordinates of the predicted extremum point EaP described above, the arithmetic system 65 calculates from the regression equation 2 coordinates (xbP, ybP) of a predicted local extremum point EbP at the predictive use time TP at which the past polishing pad is expected to reach the replacement time.

Further, the arithmetic system 65 determines a regression equation 3 from coordinates of the local extremum point Ec1 of the past histogram H1 and coordinates of the local extremum point Ec2 of the past histogram H2. The coordinates of the local extremum point Ec1 of the past histogram H1 are (xc1, yc1), and the coordinates of the local extremum point Ec2 of the past histogram H2 are (xc2, yc2). In this embodiment, since the number of local extremum points is two, which are the local extremum points Ec1 and Ec2, the regression equation 3 determined is a linear expression. In the same manner as determining the coordinates of the predicted extremum point EaP described above, the arithmetic system 65 calculates from the regression equation 3 coordinates (xcP, ycP) of a predicted local extremum point EcP at the predictive use time TP at which the past polishing pad is expected to reach the replacement time.

As shown in FIG. 19B, the arithmetic system 65 determines a regression equation expressed by a dashed-dotted line from the plurality of predicted local extremum points EaP, EbP, and EcP calculated discussed above. In the present embodiment, since the number of predicted local extremum points is three, which are the predicted local extremum points EaP, EbP, and EcP, this regression equation determined is a quadratic expression. The arithmetic system 65 produces from the determined regression equation a predictive histogram HP indicating that the past polishing pad has reached the replacement time. The predictive histogram HP is stored in the memory 65a of the arithmetic system 65. The arithmetic system 65 judges the surface property of the polishing pad 2 using this predictive histogram HP.

The arithmetic system 65 compares a shape of the histogram produced based on the surface data of the polishing pad 2 with a shape of the predictive histogram HP, and calculates a degree of similarity of the shape of the histogram to the shape of the predictive histogram HP. Comparing the shape of the produced histogram with the shape of the predictive histogram HP is performed in the same manner as comparing the shape of the histogram with the shape of the reference histogram described above. The shapes of the histograms to be compared may be shapes of the entire histograms or shapes of parts of the histograms. For example, the degree of similarity may be calculated by comparing a shape of the histogram within a range of the distance D1 to the distance D2 in the produced histogram with the shape of the predictive histogram.

The arithmetic system 65 judges the surface property of the polishing pad 2 based on the calculated degree of similarity. In one embodiment, the arithmetic system 65 judges the surface property of the polishing pad 2 such that “the polishing pad 2 has reached a replacement time” when the calculated degree of similarity is larger than a predetermined similarity threshold value. The degree of similarity and the similarity threshold value may be expressed by a percentage of 0% to 100%. For example, the arithmetic system 65 compares the shape of the histogram produced based on the surface data of the polishing pad 2 with the shape of the predictive histogram to calculate the degree of similarity, and may judge the surface property of the polishing pad 2 such that “the polishing pad 2 has reached a replacement time” when the degree of similarity is larger than the predetermined similarity threshold value of 90%.

In the present embodiment, the arithmetic system 65 produces the predictive histogram indicating that the past polishing pad has reached the replacement time from the two past histograms produced based on the two past surface data representing the surface properties of the past polishing pad at the use times T1 and T2. In one embodiment, the arithmetic system 65 may produce the predictive histogram indicating that the past polishing pad has reached the replacement time from three or more past histograms produced based on three or more past surface data representing the past surface properties of the past polishing pad at three or more use times. In this case, the regression equation determined to produce the predictive histogram may be a polynomial equation according to the number of past histograms.

In this embodiment, the arithmetic system 65 judges the surface property of the polishing pad 2 using one predictive histogram HP at the predictive use time TP, while in one embodiment, the arithmetic system 65 may judge the surface property of the polishing pad 2 using a plurality of predictive histograms at a plurality of predictive use times which are points in time when the past polishing pad is predicted to reach the replacement time.

Next, a method of judging the surface property of the polishing pad 2 using a trained model 67 that has been constructed by machine learning will be described. In this embodiment, as shown in FIG. 5, the arithmetic system 65 has the trained model 67 stored in the memory 65a. The trained model 67 is constructed by machine learning. Examples of the machine learning include SVR method (support vector regression method), PLS method (partial least squares method: Partial Least Squares), deep learning method (deep structured learning method), random forest method, and decision tree method. In one example, the trained model 67 is constituted of a neural network constructed by the deep learning method.

In this embodiment, training data for use in constructing the trained model 67 includes shapes of training histograms, and further includes degrees of deterioration corresponding to the training histograms which are correct labels. Each degree of deterioration is a numerical value that indicates a degree of deterioration of polishing pad 2, and can be expressed by a predetermined manner, such as a percentage of 0% to 100%, a value of 1 to 10, or a scale of 1 to 5. For example, when the degree of deterioration is expressed by a percentage of 0% to 100%, a degree of deterioration of 0% indicates that polishing pad 2 is new, and a degree of deterioration of 100% indicates that polishing pad 2 has reached the replacement time.

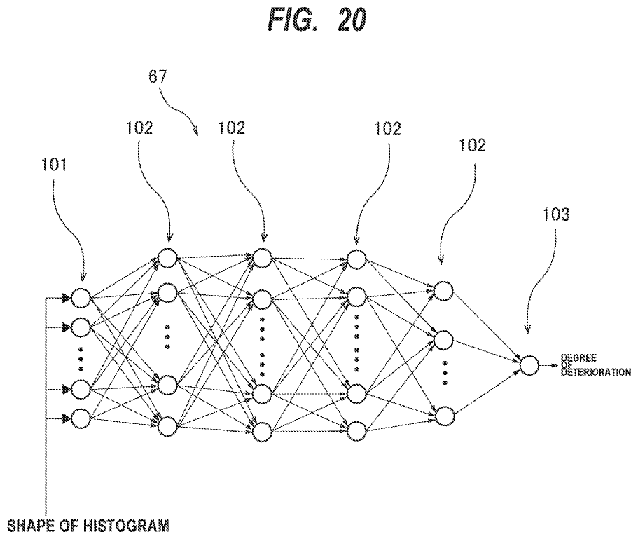

FIG. 20 is a schematic diagram showing an example of the trained model 67 constructed using the deep learning method. The trained model 67 has an input layer 101, a plurality of hidden layers (also referred to as intermediate layers) 102, and an output layer 103. The trained model 67 shown in FIG. 20 has four hidden layers 102, while the configuration of the trained model 67 is not limited to the embodiment shown in FIG. 20.

Constructing of the trained model 67 using the deep learning is performed as follows. A shape of the training histogram is input into the input layer 101 shown in FIG. 20. The training histogram is a histogram produced based on training surface data indicating a surface property of a training polishing pad. The surface data generator 41 generates training surface data containing a plurality of training shape index values representing the surface property of the training polishing pad. The arithmetic system 65 produces the training histogram indicating a distribution of the plurality of training shape index values based on the training surface data.

Measuring of the training shape index value and generating of the training surface data containing the plurality of training shape index values are performed in the same manner as measuring of the shape index value and generating of the surface data containing the plurality of shape index values by the surface data generator 41 described above.

The trained model 67 is configured to output from the output layer 103 a degree of deterioration of the polishing pad corresponding to a histogram that has been input into the input layer 101. In the machine learning for constructing the trained model 67, the arithmetic system 65 compares the degree of deterioration output from the output layer 103 with a degree of deterioration (correct label) of the polishing pad corresponding to the training histogram, and adjusts parameters (e.g., weight, threshold value, etc.) of nodes (neurons) so as to minimize an error between these degrees of deterioration. As a result, the trained model 67 is trained to output an appropriate degree of deterioration from the output layer 103 based on the histogram input to the input layer 101.

The trained model 67 is constructed by repeating the above-described learning using a plurality of training histograms produced based on training surface data representing surface properties of a plurality of training polishing pads. The trained model 67 constructed by the machine leaning may basically has low prediction accuracy for input data that has never been experienced. Therefore, an accuracy of the degree of deterioration output from the trained model 67 can be improved by using a large number of training histograms produced based on training surface data of a large number of training polishing pads whose surface properties vary in different manners.

Determining of the surface property of the polishing pad 2 using the trained model 67 is performed as follows. The surface data generator 41 generates surface data containing a plurality of shape index values indicating the surface property of the polishing pad 2. The arithmetic system 65 produces a histogram indicating a distribution of the plurality of shape index values based on the generated surface data. The arithmetic system 65 inputs a shape of the produced histogram into the input layer 101 of the trained model 67 constructed by the machine learning.

The arithmetic system 65 judges the surface property of the polishing pad 2 by performing arithmetic operations according to an algorithm defined by the trained model 67 using the shape of the histogram input to the input layer 101 of the trained model 67, and outputting from the output layer 103 the degree of deterioration corresponding to the histogram. In one embodiment, the arithmetic system 65 judges the surface property of the polishing pad 2 such that “the polishing pad 2 has reached a replacement time” when the output degree of deterioration is larger than a predetermined deterioration threshold value. For example, the arithmetic system 65 may judge the surface property of the polishing pad 2 such that “the polishing pad 2 has reached a replacement time” when the degree of deterioration is expressed by a percentage in a range of 0% to 100%, and the calculated degree of deterioration is larger than a predetermined deterioration threshold value of 90%.

According to the present embodiment, the degree of deterioration of the polishing pad 2 can be determined from the output degree of deterioration. For example, when the output degree of deterioration is 50%, the degree of deterioration of the polishing pad 2 can be determined to be half of the degree of deterioration at the replacement time of the polishing pad 2.

In each of the above-described embodiments, the arithmetic system 65 may generate an alarm to urge a replacement of the polishing pad 2 when the surface property of the polishing pad 2 is judged such that “the polishing pad 2 has reached a replacement time”. Thus, the surface property judging system 40 can appropriately judge the surface property of the polishing pad 2.

In one embodiment, the arithmetic system 65 may generate an alarm to urge a replacement of the polishing pad 2 when the use time of the polishing pad 2 has exceeded a predetermined time, or when the number of polished substrates W has exceeded a predetermined number and the surface property of the polishing pad 2 has not yet been judged such that “the polishing pad 2 has reached a replacement time” in each of the above-described embodiments.

In one embodiment, the arithmetic system 65 may judge the surface property of the polishing pad 2 according to a combination of the embodiments described above. For example, the arithmetic system 65 performs a judgement process of the surface property of the polishing pad 2 using the similarity to the reference histogram of the past polishing pad that has reached its replacement time, performs a judgement process of the surface property of the polishing pad 2 using the similarity to the predictive histogram indicating that the polishing pad has reached its replacement time, and then judges that “the polishing pad 2 has reached a replacement time” when either one of these two judgement processes results in the fact that “the polishing pad 2 has reached a replacement time”. In another example, the arithmetic system 65 performs a judgement process of the surface property of the polishing pad 2 using the similarity to the reference histogram of the past polishing pad that has reached its replacement time, performs a judgement process of the surface property of the polishing pad 2 using the similarity to the predictive histogram indicating that the polishing pad has reached its replacement time, and then judges that “the polishing pad 2 has reached a replacement time” when both of these two judgement processes result in the fact that “the polishing pad 2 has reached a replacement time”.

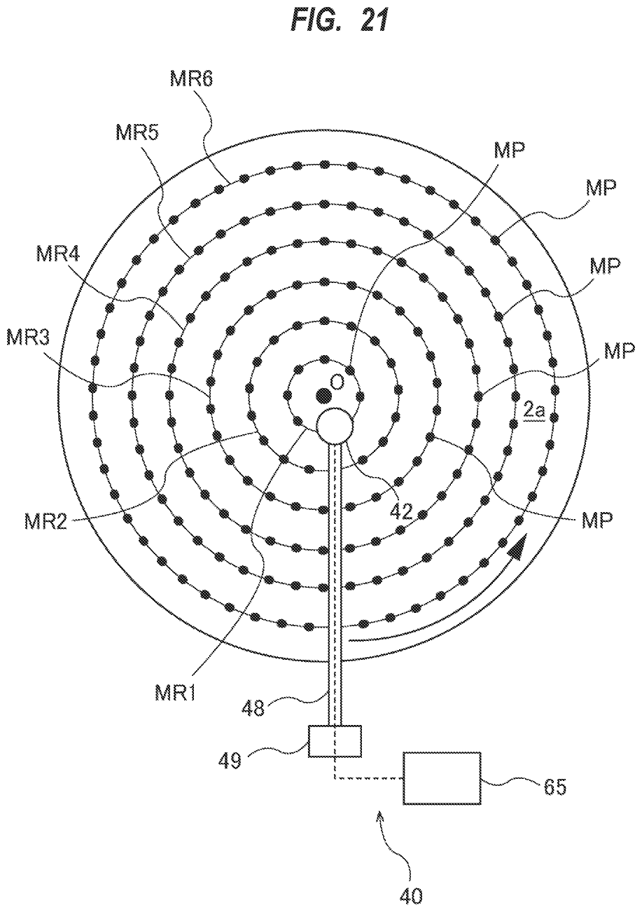

FIG. 21 is a diagram showing a plurality of measurement regions MR1 to MR6 according to another embodiment of the surface property judging system 40. The surface property judging system 40 of the present embodiment is configured to obtain the shape index values in a plurality of measurement regions MR1 to MR6 located on the polishing surface 2a of the polishing pad 2. The plurality of measurement regions MR1 to MR6 are arranged along the radial direction of the polishing pad 2. Configurations and operations of this embodiment, which will not be particularly described, are the same as those of the above-described embodiments, and duplicated descriptions will be omitted. In this embodiment, the number of measurement regions is six, while the number of measurement regions is not limited to this embodiment, and may be five or less, or seven or more.

The plurality of measurement regions MR1 to MR6 are a plurality of concentric circular regions arranged along the radial direction of the polishing pad 2 and centered at a rotation center of the polishing pad 2. In one example, the plurality of measurement regions MR1 to MR6 may be arranged at equal intervals in the radial direction of the polishing pad 2. Each of the measurement regions MR1 to MR6 is an annular region. The measuring head 42 directs the light to the polishing surface 2a of the rotating polishing pad 2 at predetermined time intervals (e.g., every 5 milliseconds) in each of the plurality of measurement regions MR1 to MR6, and continuously measures the shape index value at each of a plurality of measurement points MR on the plurality of measurement regions MR1 to MR6 based on the reflected light from the polishing surface 2a. In this embodiment, the shape index value is the distance D to the polishing surface 2a of the polishing pad 2. The measuring head 42 is moved from one measurement region to another measurement region by the above-described measuring-head moving mechanism 47, and measures the shape index values at the plurality of measurement regions MR1 to MR6.

The surface data generator 41 generates a plurality of region surface data containing the plurality of shape index values measured by the measuring head 42 for the plurality of measurement regions MR1 to MR6. The plurality of region surface data corresponding to the measurement regions MR1 to MR6 are transmitted to the arithmetic system 65. The arithmetic system 65 produces a histogram indicating a distribution of the plurality of shape index values of each region surface data based on the plurality of region surface data transmitted from the surface data generator 41. In other words, the arithmetic system 65 produces a plurality of histograms corresponding to the plurality of measurement regions MR1 to MR6. In this embodiment, six histograms are produced.

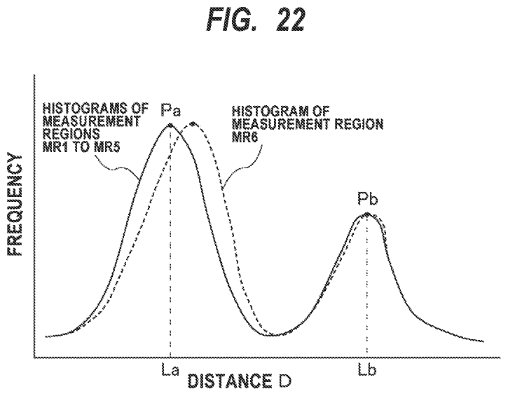

FIG. 22 is a diagram showing an example of the plurality of histograms generated based on the region surface data of the plurality of measurement regions MR1 to MR6. In the example of FIG. 22, shapes of five histograms of the measurement regions MR1 to MR5 are approximately the same, and are represented by one histogram indicated by a solid line. A position of a peak Pa, i.e., a value La of the distance D of a histogram of the measurement region MR6 indicated by a dashed line is larger than that of the histograms of the measurement regions MR1 to MR5. This indicates that the measurement region MR6 has been worn more than the measurement regions MR1 to MR5 in the polishing surface 2a of the polishing pad 2 as described with reference to FIG. 10A.

The arithmetic system 65 judges surface properties of the plurality of measurement regions MR1 to MR6 of the polishing pad 2 based on the plurality of histograms corresponding to the plurality of measurement regions MR1 to MR6. Judging of the surface property of the polishing pad 2 includes judging of relative surface properties of the plurality of measurement regions MR1 to MR6 of the polishing pad 2. In this embodiment, the arithmetic system 65 judges that “a degree of wear of the measurement region MR6 is larger than those of the measurement regions MR1 to MR5”.

The judging result of the surface properties of the plurality of measurement regions MR1 to MR6 of the polishing pad 2 may be used to reflect dressing conditions of the dresser 20. For example, the dressing conditions are determined such that the surface properties of the plurality of measurement regions MR1 to MR6 become uniform based on the judging result “a degree of wear of the measurement region MR6 is larger than that of the measurement regions MR1 to MR5” determined by the arithmetic system 65. The dressing conditions include, e.g., dressing time, dressing pressure, and the like. This determination of the dressing conditions may be performed by an operator, or may be performed by the polishing controller 60. In the case where the determination of the dressing conditions is performed by the polishing controller 60, the arithmetic system 65 transmits judging results of the surface properties of the plurality of measurement regions MR1 to MR6 to the polishing controller 60. The polishing controller 60 instructs the dresser 20 to dress the polishing surface 2a of the polishing pad 2 under the determined dressing conditions.

The arithmetic system 65 may calculate a degree of regional deterioration indicating a degree of deterioration of the surface property of each of the measurement regions MR1 to MR6 based on positions of peaks Pa, i.e., values La of the distance D, of the plurality of histograms corresponding to the plurality of measurement regions MR1 to MR6 to thereby judge the surface properties of the plurality of measurement regions MR1 to MR6 of the polishing pad 2. The degree of regional deterioration can be expressed by a predetermined manner, such as a percentage of 0% to 100%, a value of 1 to 10, or a scale of 1 to 5. For example, in the case where the degree of regional deterioration is represented by a percentage in a range of 0% to 100%, the arithmetic system 65 calculates the degree of regional deterioration of the measurement regions MR1 to MR5 as 10% and the degree of regional deterioration of the measurement region MR6 as 30%, so that the arithmetic system 65 can judge the surface properties of the plurality of measurement regions MR1 to MR6 of the polishing pad 2. The polishing controller 60 determines the dressing conditions based on the degrees of regional deteriorations of the measurement regions MR1 to MR6, so that the surface properties of the plurality of measurement regions MR1 to MR6 can be made uniform.

In the present embodiment, the arithmetic system 65 judges the surface properties of the plurality of measurement regions MR1 to MR6 of the polishing pad 2 based on the peak positions of the plurality of histograms corresponding to the plurality of measurement regions MR1 to MR6, while in the embodiment, the arithmetic system 65 may judge the surface properties of the plurality of measurement regions MR1 to MR6 of the polishing pad 2 using one or a combination of peak heights of the plurality of histograms corresponding to the plurality of measurement regions MR1 to MR6, the degree of similarity to the reference histogram produced based on the reference surface data representing the surface property of the past polishing pad that has reached the replacement time, the degree of similarity to the predictive histogram indicating that the past polishing pad has reached the replacement time, and the trained model 67 constructed by the machine learning.

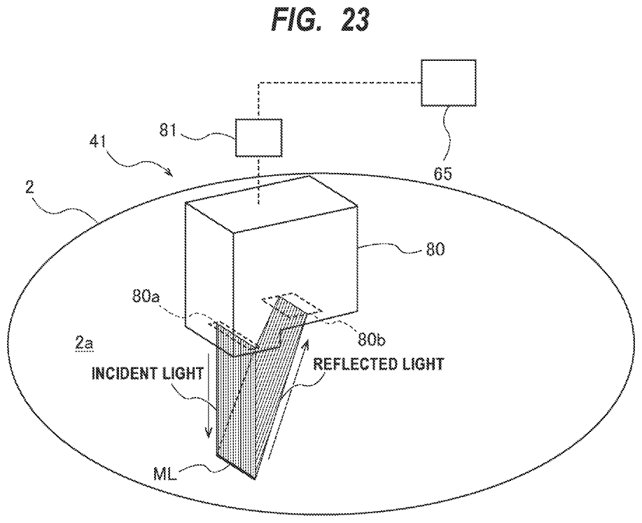

The surface data generator 41 of the embodiments described above includes the distance sensor as the measuring head 42, and is configured to measure the distance D from the lower end of the measuring head 42 to the polishing surface 2a of the polishing pad 2 as a shape index value, while the configuration of the surface data generator 41 is not limited to these embodiments. FIG. 23 is a schematic diagram showing another embodiment of the surface data generator 41. Configuration and operations of this embodiment, which will not be particularly described, are the same as those of the above-described embodiment, and duplicated descriptions will be omitted.

A surface data generator 41 shown in FIG. 23 includes a measuring head 80 having a light source 80a and a light receiving element 80b, and a data processer 81. The measuring head is a shape measuring sensor configured to measure a surface shape of a target object. An example of the measuring head 80 is a non-contact laser displacement sensor, and a commercially-available two-dimensional profile measuring device can be used. As shown in FIG. 23, the measuring head 80 directs linear light (linear laser light) from the light source 80a to the polishing surface 2a of the polishing pad 2, and receives reflected light from the polishing surface 2a by the light receiving element 80b. The measuring head 80 measures the surface shape of the polishing pad 2 along a measurement line ML based on the reflected light.

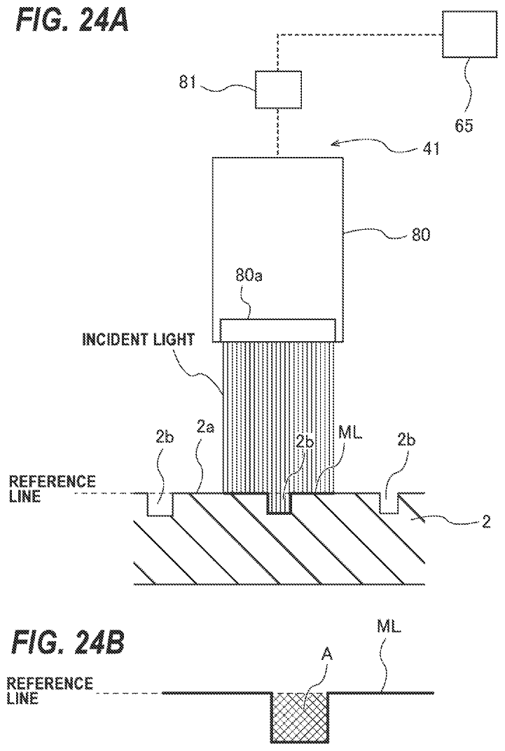

FIG. 24A is a schematic diagram illustrating measuring the surface shape of the polishing pad 2 by the surface data generator 41 shown in FIG. 23. FIG. 24B is a diagram showing a measurement result of the surface shape of the polishing pad 2 shown in FIG. 24A. FIG. 24A is a front view of the measuring head 80. The line light emitted from the light source is reflected off the polishing surface 2a along the surface shape of the polishing surface 2a of the polishing pad 2. The surface data generator 41 can measure the surface shape of the polishing pad 2 along the measurement line ML corresponding to a width of the line light.

The surface data generator 41 is configured to measure an area A of the recess 2b indicated by cross hatching in FIG. 24B as the shape index value representing the surface property of the polishing pad 2. The measuring head 80 is coupled to the data processer 81. A measured value obtained by the measuring head 80 is transmitted to the data processer 81. The data processer 81 calculates the area A of the recess 2b up to a preset reference line. The reference line is, for example, located at the same height as the polishing surface 2a of the polishing pad 2. In the same manner as the embodiment described with reference to FIG. 7, the measuring head 80 directs the line light to the polishing surface 2a of the rotating polishing pad 2 at predetermined time intervals (e.g., every 5 milliseconds), and measures the area A of the recess 2b formed in the polishing surface 2a of the polishing pad 2 based on the reflected light from the polishing pad 2a.

The measuring head 80 continuously measures the areas A of the recess 2b formed in the polishing surface 2a along a plurality of measurement lines ML for a predetermined period of time. In one embodiment, a plurality of measured values of the area A along each of the plurality of measurement lines ML may be obtained in one continuous measuring operation. One continuous measuring operation may be performed each time one substrate W is polished, or may be performed each time a predetermined number of substrates W are polished.

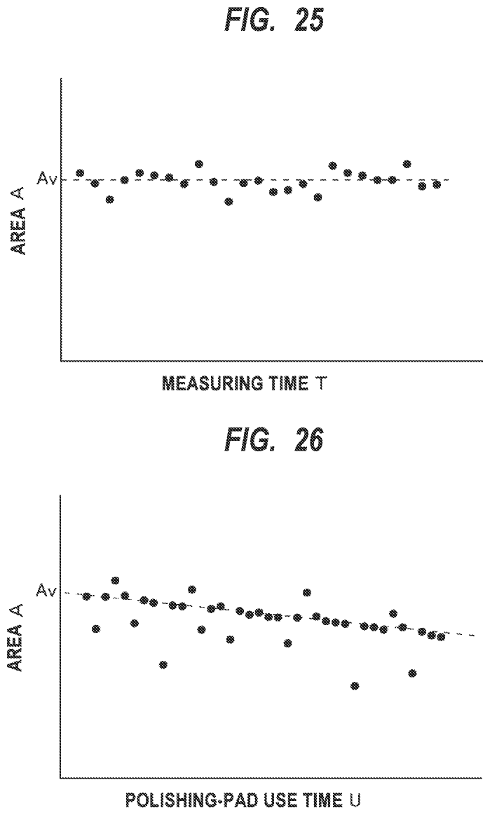

FIG. 25 is a graph showing a relationship between the area A measured along the plurality of measurement lines ML and measuring time T. In FIG. 25, vertical axis represents the area A, and horizontal axis represents the measuring time T. The graph shown in FIG. 25 has been obtained by rotating the polishing pad 2 and measuring the plurality of measurement lines ML on the polishing surface 2a by the measuring head 80 in one continuous measuring operation. The polishing pad 2 used in this measuring is in an initial condition of use with no wear. FIG. 26 is a graph showing a relationship between the area A and polishing-pad use time U measured along the plurality of measurement lines ML. In FIG. 26, measured values of the area A obtained in a plurality of continuous measuring operations that have been conducted from the beginning to the end of use of the polishing pad 2 are plotted. The graph shown in FIG. 26 may be a graph plotting a relationship between average Av of measured values obtained in each of the plurality of continuous measuring operations and the polishing-pad use time U. In FIG. 26, vertical axis represents the area A, and horizontal axis represents the polishing-pad use time U. The measured value of the area A changes with the polishing-pad use time U.

As shown in FIG. 26, the average Av of the measured values of the plurality of areas A becomes smaller with the use time of the polishing pad 2. This indicates that the polishing pad 2 has been worn and the area A of the recess 2b formed in the polishing surface 2a become smaller as shown in FIG. 10A, or the recess 2b has been clogged with the polishing debris or the like and the area A become smaller as shown in FIG. 10B. Therefore, degree of wear of the polishing pad 2 or degree of clogging of the recess 2b can be estimated from the change in the measured value of the area A.

As shown in FIG. 23, the data processer 81 of the surface data generator 41 is coupled to the arithmetic system 65. The surface data generator 41 generates surface data containing a plurality of shape index values measured by the measuring head 80 and calculated by the data processer 81. The generated surface data are transmitted to the arithmetic system 65. The arithmetic system 65 produces a histogram indicating a distribution of the plurality of shape index values based on the surface data transmitted from the surface data generator 41. In this embodiment, the arithmetic system 65 produces a histogram indicating a distribution of the plurality of measured values of the area A.

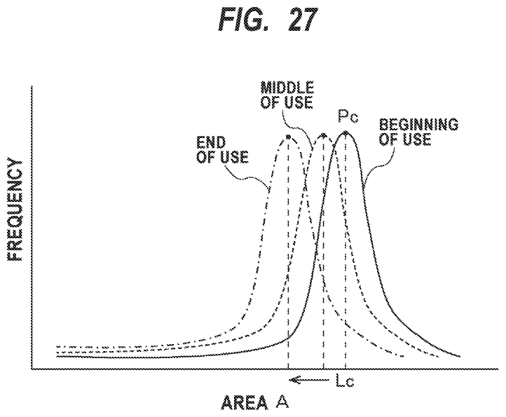

FIG. 27 is a diagram showing an example of a histogram that changes with the use time of the polishing pad 2. In FIG. 27, vertical axis represents frequency, and horizontal axis represents the area A. The frequency corresponds to the number of data for each measured value of the area A. The arithmetic system 65 produces a histogram indicating a distribution of the measured values of the area A, which are the shape index values of the polishing pad 2, obtained in one continuous measuring operation. Each of three histograms in FIG. 27 indicates a distribution of the measured values of the area A, which are the shape index values of the polishing pad 2, obtained in one continuous measuring operation. A histogram indicated by a solid line indicates a distribution of the measured values of the area A obtained at the beginning of use of the polishing pad 2. A histogram indicated by a dashed line indicates a distribution of the measured values of the area A obtained during the middle of use of the polishing pad 2. A histogram indicated by a dashed-dotted line indicates a distribution of the measured values of the area A obtained at the end of use of the polishing pad 2.

One peak appears in each of the histograms of the beginning, the middle, and the end of use in FIG. 27. A position of the peak Pc in each histogram moves with the use time of the polishing pad 2. The position of the peak Pc, i.e., a value Lc of the area A, decreases with the use time of the polishing pad 2. This is indicates that the polishing pad 2 has been worn or an amount of the polishing debris clogging the recesses 2b formed in the polishing surface 2a increases, with the use time of the polishing pad 2, as described with reference to FIGS. 10A and 10B.

In the same manner as the embodiments described above, the arithmetic system 65 judges the surface property of the polishing pad 2 based on the produced histograms using one or a combination of the predetermined position threshold value, the predetermined height threshold value, the degree of similarity to the reference histogram produced based on the reference surface data representing the surface property of the past polishing pad that has reached the replacement time, the degree of similarity to the predictive histogram indicating that the past polishing pad has reached the replacement time, and the trained model 67 constructed by the machine learning.

In one embodiment, the surface property judging system 40 may include a plurality of surface data generators 41. The plurality of surface data generators 41 may have the same type of a plurality of measuring heads 80, or may be a combination of the surface data generator 41 having the measuring head 42 described with reference to FIG. 5 and the surface data generator 41 having the measuring head 80 described with reference to FIG. 23. The plurality of surface data generators 41 may include a plurality of measuring heads 42 that measure with different measurement spot diameters, or may include a plurality of measuring heads 80 that measure with different widths of line light.

Measuring of the shape index value of the polishing pad 2 by the surface data generator 41 may be performed while the polishing pad 2 is rotated as described above or the rotation of the polishing pad 2 is stopped.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A surface property judging method comprising:
rotating a polishing table together with a polishing pad which is supported by the polishing table;
generating surface data by a surface data generator, the surface data containing a plurality of shape index values representing a surface property of the polishing pad;
producing a histogram indicating a distribution of the plurality of shape index values based on the surface data; and
judging the surface property of the polishing pad based on the histogram.

2. The surface property judging method according to claim 1, wherein judging the surface property of the polishing pad is performed based on a position of a peak appearing in the histogram.

3. The surface property judging method according to claim 1, wherein judging the surface property of the polishing pad is performed based on a height of a peak appearing in the histogram.

4. The surface property judging method according to claim 1, further comprising:
generating reference surface data containing a plurality of reference shape index values representing a surface property of a past polishing pad that has reached a replacement time; and
producing a reference histogram indicating a distribution of the plurality of reference shape index values based on the reference surface data,
wherein judging the surface property of the polishing pad is performed based on a degree of similarity of a shape of the histogram to a shape of the reference histogram.

5. The surface property judging method according to claim 1, further comprising:
generating reference surface data containing a plurality of reference shape index values representing a surface property of a past polishing pad that has not yet reached a replacement time; and
producing a reference histogram indicating a distribution of the plurality of reference shape index values based on the reference surface data,
wherein judging the surface property of the polishing pad based on the histogram comprises calculating a degree of similarity of a shape of the histogram to a shape of the reference histogram, and judging the surface property of the polishing pad based on the degree of similarity.

6. The surface property judging method according to claim 1, further comprising:
generating a plurality of past surface data containing a plurality of past shape index values representing surface properties of a past polishing pad at a plurality of use times;
producing a plurality of past histograms indicating distributions of the plurality of past shape index values based on the plurality of past surface data; and
producing a predictive histogram from the plurality of past histograms, the predictive histogram indicating that the past polishing pad has reached a replacement time,
wherein judging the surface property of the polishing pad based on the histogram comprises calculating a degree of similarity of a shape of the histogram to a shape of the predictive histogram, and judging the surface property of the polishing pad based on the degree of similarity.

7. The surface property judging method according to claim 1, wherein judging the surface property of the polishing pad includes judging whether the polishing pad has reached a replacement time.

8. The surface property judging method according to claim 1, wherein judging the surface property of the polishing pad is performed by inputting a shape of the histogram into a trained model constructed by machine learning, and outputting a degree of deterioration from the trained model.

9. The surface property judging method according to claim 1, wherein
producing the surface data comprises generating a plurality of region surface data by the surface data generator, the plurality of region surface data containing a plurality of shape index values representing surface properties of a plurality of measurement regions of the polishing pad, the plurality of measurement regions being arranged along a radial direction of the polishing pad,
producing the histogram comprises producing a plurality of histograms corresponding to the plurality of measurement regions based on the plurality of region surface data, and
judging the surface property of the polishing pad comprises judging the surface properties of the plurality of measurement regions based on the plurality of histograms.

10. The surface property judging method according to claim 1, wherein the surface data generator includes a distance sensor or a shape measuring sensor.

11. A surface property judging system comprising:
a surface data generator configured to generate surface data containing a plurality of shape index values representing a surface property of a rotating polishing pad; and
an arithmetic system configured to produce a histogram indicating a distribution of the plurality of shape index values based on the surface data, and judge the surface property of the polishing pad based on the histogram.

12. The surface property judging system according to claim 11, wherein the arithmetic system is configured to judge the surface property of the polishing pad based on a position of a peak appearing in the histogram.

13. The surface property judging system according to claim 11, wherein the arithmetic system is configured to judge the surface property of the polishing pad based on a height of a peak appearing in the histogram.

14. The surface property judging system according to claim 11, wherein the arithmetic system is configured to generate reference surface data containing a plurality of reference shape index values representing a surface property of a past polishing pad that has reached a replacement time, produce a reference histogram indicating a distribution of the plurality of reference shape index values based on the reference surface data, and judge the surface property of the polishing pad based on a degree of similarity of a shape of the histogram to a shape of the reference histogram.

15. The surface property judging system according to claim 11, wherein the arithmetic system is configured to generate reference surface data containing a plurality of reference shape index values representing a surface property of a past polishing pad that has not yet reached a replacement time, produce a reference histogram indicating a distribution of the plurality of reference shape index values based on the reference surface data, calculate a degree of similarity of a shape of the histogram to a shape of the reference histogram, and judge the surface property of the polishing pad based on the degree of similarity.

16. The surface property judging system according to claim 11, wherein the arithmetic system is configured to generate a plurality of past surface data containing a plurality of past shape index values representing surface properties of a past polishing pad at a plurality of use times, produce a plurality of past histograms indicating distributions of the plurality of past shape index values based on the plurality of past surface data, produce a predictive histogram indicating that the past polishing pad has reached a replacement time from the plurality of past histograms, calculate a degree of similarity of a shape of the histogram to a shape of the predictive histogram, and judge the surface property of the polishing pad based on the degree of similarity.

17. The surface property judging system according to claim 11, wherein the arithmetic system is configured to judge whether the polishing pad has reached a replacement time.

18. The surface property judging system according to claim 11, wherein
the arithmetic system has a trained model constructed by machine learning, and
the arithmetic system is configured to judge the surface property of the polishing pad by inputting a shape of the histogram into the trained model, and outputting a degree of deterioration from the trained model.

19. The surface property judging system according to claim 11, wherein
the surface data generator is configured to generate a plurality of region surface data containing a plurality of shape index values representing surface properties of a plurality of measurement regions of the polishing pad, the plurality of measurement regions being arranged along a radial direction of the polishing pad, and
the arithmetic system is configured to produce a plurality of histograms corresponding to the plurality of measurement regions based on the plurality of region surface data, and judge the surface properties of the plurality of measurement regions of the polishing pad based on the plurality of histograms.

20. The surface property judging system according to claim 11, wherein the surface data generator includes a distance sensor or a shape measuring sensor.
